(19) United States
(12) Patent Application Publication
(10) Pub. No.: US 2025/0063857 A1
(43) Pub. Date: Feb. 20, 2025

(54) COMPOUND SEMICONDUCTOR SUBSTRATE

(71) Applicant: NATIONAL INSTITUTE OF ADVANCED INDUSTRIAL SCIENCE AND TECHNOLOGY, Tokyo (JP)

(72) Inventor: Hisashi YAMADA, Tsukuba-shi (JP)

(21) Appl. No.: 18/723,840

(22) PCT Filed: Dec. 19, 2022
(86) PCT No.: PCT/JP2022/046582

§ 371 Date: Jun. 24, 2024

(30) Foreign Application Priority Data
Dec. 27, 2021 (JP) 2021-212419

(51) Int. Cl. H01L 33/12

(52) U.S. Cl. CPC H01L 33/12

(57) ABSTRACT

This compound semiconductor substrate has a base layer having an in-plane lattice constant of a, a stress relaxation layer that relaxes strain that is received from the base layer and a functional layer having an in-plane lattice constant of b (a≠b), the base layer, the stress relaxation layer and the functional layer are disposed in order of the base layer, the stress relaxation layer and the functional layer, in the functional layer, a region where a lattice is relaxed from a crystal lattice of the base layer is dominant, and the threading dislocation density of the functional layer is lower than 2.0×10⁹ cm⁻².

### TECHNICAL FIELD

The present invention relates to a compound semiconductor substrate. Priority is claimed on Japanese Patent Application No. 2021-212419, filed Dec. 27, 2021, the content of which is incorporated herein by reference.

### BACKGROUND ART

The number of photoelectric elements (compound semiconductor elements) in which a compound semiconductor is used such as light emitting diodes (LEDs), semiconductor lasers (LD; laser diode, VCSEL; vertical cavity surface emitting laser) and field effect transistors (FET) have been put into practical use. In order to produce a compound semiconductor element suitable for the purpose, crystal growth for laminating the same material as or a dissimilar material from a substrate on the substrate is necessary. The crystal growth of a dissimilar material is called epitaxial growth, and compressive strain or tensile strain is introduced into a plane due to a difference in the in-plane lattice constant or the thermal expansion coefficient. For example, since the in-plane lattice constant in the c plane of GaN is larger than the in-plane lattice constant of AlN by approximately 2.4%, in a case where the epitaxial growth of GaN is caused on an AlN substrate, a GaN epitaxial layer receives compressive strain in the plane of the substrate. When the thickness of the epitaxial layer that is considered to be necessary for semiconductor elements is set to be large, strain energy is accumulated in the epitaxial layer, lattice relaxation occurs in the end to relax the strain energy, misfit dislocation is introduced, and surface roughening is caused.

The band gap of an AlGaN compound semiconductor can be changed from 3.4 eV up to 6.2 eV by controlling the composition ratio between Al and Ga, and the band gap corresponds to light emission wavelengths of 360 nm through 200 nm. For example, as shown in Non-Patent Document 1, a deep ultraviolet LED for which AlGaN having an Al composition ratio of 0.7 to near 0.5 is used covers light emission wavelengths in a range of 300 nm to 250 nm. Deep ultraviolet LEDs have a wide application range such as a bactericidal effect against bacteria or viruses, and technical studies regarding performance improvement thereof are thus underway. Particularly, there is an ongoing study regarding the influence of the density of dislocations that are present in the crystals of an AlGaN functional layer on the light emission efficiency of LEDs.

For example, Non-Patent Document 2 discloses the crystal characteristics of a semiconductor substrate composed of an AlN freestanding substrate, a superlattice structure formed on the AlN freestanding substrate and composed of AlₓGa₁₋ₓN/AlyGa_{1-y}N with a repetition period count of 10, an AlGaN functional layer (Al=0.5) on the superlattice layer, an active layer formed on the functional layer and a contact layer formed on the active layer. It is recognized that there is a linear relationship between the lattice relaxation ratio of the AlGaN functional layer (Al=0.5) with respect to the AlN freestanding substrate and the X-ray rocking curve full width at half maximum in an asymmetrical plane (102) of the AlGaN functional layer, the full width at half maximum increases from 180 up to 420 arcsec when the lattice relaxation ratio reaches 70% from 0%, the full width at half maximum increases up to 720 arcsec at the lattice relaxation ratio of 100% and an LED formed on the AlGaN functional layer emits light at 300 nm.

For example, Non-Patent Document 3 discloses the structure and crystal characteristics of a semiconductor substrate composed of an AlN freestanding substrate, a 400 nm AlN base layer formed on the AlN freestanding substrate, a 50 nm inclined layer formed on the base layer and having an Al composition ratio linearly changed from zero and an n-type AlGaN functional layer (Al=0.45 to 0.75) formed on the inclined layer and having a thickness of 0.5 to 1.3 μm. Regarding the X-ray rocking curve full widths at half maximum in a symmetrical plane (002) and an asymmetrical plane (102) of the AlGaN functional layer, in a pseudomorphic state where the functional layer coincides with the base layer in terms of the in-plane lattice constant, the (002) full width at half maximum is within a range of 64 to 81 arcsec, and the (102) full width at half maximum is within a range of 84 to 104 arcsec. It is recognized that, in a case where the Al composition of the functional layer is low or a case where the thickness of the functional layer is thick, the in-plane lattice constant of the functional layer does not coincide with the in-plane lattice constant of the AlN base layer, lattice relaxation occurs, the X-ray rocking curve full width at half maximum of the symmetrical plane (002) and the X-ray rocking curve full width at half maximum of the asymmetrical plane (102) each significantly deteriorate to 239 arcsec or 302 arcsec, and furthermore, surface roughening is significant on the functional layer having an Al composition ratio of 0.6 and a thickness of 0.5 μm, in which lattice relaxation has occurred.

There is a report of an AlGaN deep ultraviolet LED on a sapphire substrate instead of an AlN freestanding substrate. Sapphire substrates are relatively inexpensive, large-diameter substrates can be procured therefrom, and mass production is thus expected. However, since the difference in the in-plane lattice constant between the sapphire substrate and an AlGaN functional layer is 13% to 16%, when the AlGaN functional layer is directly grown on the sapphire substrate, the threading dislocation density increases up to an order of magnitude of 10 (cm⁻²). Therefore, an AlN base layer is first formed on the sapphire substrate. Here, the density of dislocations that are present in the AlN base layer is an order of magnitude of eight or nine (cm⁻²), which is three digits higher than that of the AlN freestanding substrate, and the influence thereof on the light emission efficiency of the deep ultraviolet LED is large. That is, it is even more important to improve the quality of the AlGaN functional layer formed on the AlN base layer.

For example, Non-Patent Document 4 discloses the structure and crystal characteristics of a semiconductor substrate composed of a sapphire substrate, an AlN base layer in contact with the sapphire substrate, a superlattice layer selectively formed on a part of the base layer and composed of AlN/AlGaN, an n-type AlGaN functional layer (Al composition ratio=0.55) formed on the superlattice layer, an active layer formed on the functional layer and a contact layer formed on the active layer. In Non-Patent Document 4, it is recognized that an LED emits light at a wavelength of 290 nm. However, descriptions regarding the thickness of the superlattice layer, the Al composition ratio of AlGaN, the structure and in-plane strain are not recognized.

For example, Non-Patent Document 5 discloses the structure and crystal characteristics of a semiconductor substrate composed of a sapphire substrate, a 900 nm AlN base layer formed on the sapphire substrate, an n-type AlGaN functional layer formed on the base layer and an active layer formed on the functional layer. In Non-Patent Document 5, it is recognized from X-ray reciprocal lattice mapping from a diffraction plane (114) that, when the functional layer has an Al composition ratio of 0.57 and a thickness of 27 nm, the functional layer is in a pseudomorphic state with respect to the base layer, when the functional layer has an Al composition ratio of 0.47 and a thickness of 350 nm, the functional layer is in a metamorphic state with respect to the base layer, the lattice relaxation ratio is 55% and there is a peak at 289 nm in a photoexcitation emission spectrum (photoluminescence) at room temperature. Furthermore, it is recognized that a very slight improvement in the threading dislocation density estimated from an X-ray rocking curve is observed when the pseudomorphic state turns into a metamorphic state. For example, it is recognized that the screw threading dislocation density decreases from 6.7×10⁹ cm⁻² to 5.6×10⁹ cm⁻² and the edge threading dislocation density decreases from 1.6×10⁹ cm⁻² to 1.5×10⁹ cm⁻².

For example, Non-Patent Document 6 discloses the crystal characteristics of a semiconductor substrate composed of a sapphire substrate, an AlN base layer in contact with the sapphire substrate, a superlattice layer formed on the base layer and composed of AlN (thickness: 2.5 nm)/GaN (thickness: 1.0 to 2.5 nm), an n-type AlGaN functional layer formed on the superlattice layer, an active layer formed on the functional layer and a contact layer formed on the active layer. In Non-Patent Document 6, it is recognized from X-ray reciprocal lattice mapping from a diffraction plane (105) that the functional layer is in a metamorphic state with respect to the base layer, an LED formed on a superlattice structure emits light at a wavelength of 310 nm and roughening is extremely significant on the surface of the semiconductor substrate.

For example, Non-Patent Document 7 discloses the structure and crystal characteristics of a semiconductor substrate composed of a sapphire substrate, an AlN base layer in contact with the sapphire substrate, a superlattice layer formed on the base layer and composed of Al_{0.37}Ga_{0.63}N/Al_{0.27}Ga_{0.73}N having a repetition period count of 30 to 70 and a thickness of 14 to 7 nm, an n-type AlGaN functional layer formed on the superlattice, an active layer formed on the functional layer and a contact layer formed on the active layer. It is recognized in Non-Patent Document 7 that the total thickness of the superlattice structure is 430 nm, the lattice relaxation ratio of the functional layer with respect to the base layer is 87%, the X-ray rocking curve full width at half maximum of a diffraction plane (102) of the functional layer is 793 arcsec and an LED emits light at a wavelength of 341 nm.

For example, Non-Patent Document 8 discloses the structure and crystal characteristics of a semiconductor substrate composed of a sapphire substrate, an AlN base layer in contact with the sapphire substrate, a laminate of a first layer formed on the base layer and composed of AlGaN having an Al composition ratio of 0.6 and a second layer formed on the first layer and composed of AlGaN having an Al composition ratio of 0.6 or less, the Al composition ratio gradually decreasing as the second layer is further away from the substrate, an n-type AlGaN functional layer formed on the second layer, an active layer formed on the functional layer and a contact layer formed on the active layer. It is recognized in Non-Patent Document 8 that the lattice relaxation ratio of the functional layer with respect to the base layer is a maximum of 30%, the threading dislocation density is 1×10⁹ cm⁻² and an LED emits light at wavelengths of 316 nm to 295 nm.

For example, Patent Document 1 discloses a nitride semiconductor element including a substrate, an AlN strain buffer layer formed on the substrate and composed of AlN, a superlattice strain buffer layer formed on the AlN strain buffer layer and a nitride semiconductor layer formed on the superlattice strain buffer layer, in which the superlattice strain buffer layer is composed of AlₓGa₁₋ₓN (0≤x≤0.25) and a first layer containing Mg and a second layer composed of AlN and intentionally containing no Mg are alternately laminated to form an superlattice structure. Patent Document 1 states that the thickness of the superlattice strain buffer layer, for which AlGaN having a low GaN or Al content rate and AlN are combined together, is made to be as thin as possible to form the superlattice strain buffer layer on the substrate with favorable flatness and Mg is added to accelerate the crystal growth of AlGaN or GaN in the lateral direction, whereby the crystallinity of the nitride semiconductor layer that is laminated on the superlattice strain buffer layer can be improved.

For example, Patent Document 2 discloses a method for forming an AlGaN layer, including a step of forming a template substrate by forming a substrate and an AlN base layer having a substantially flat surface at the atomic level on the substrate and a step of forming an AlGaN functional layer on the AlN base layer, in which, in the AlGaN functional layer formation step, a superlattice structure in which a first unit layer represented by a compositional formula AlₓGa₁₋ₓN (0.5<x≤1) and a second unit layer represented by a compositional formula Al_{y}Ga_{1-y}N (0.5≤y<1 and y<x) are alternately and repeatedly laminated at a formation temperature of higher than 1000° C. and lower than 1100° C. is provided. Patent Document 2 states that it is preferable to form the superlattice structure in a thickness within a range where lattice relaxation does not occur, that is, it is possible to form an AlGaN layer while causing the coherent growth of the first unit layer and the second unit layer and to obtain an AlGaN layer having substantially the same in-plane lattice constant as the in-plane lattice constant of the surface layer and having a surface that is substantially flat at an atomic level.

For example, Patent Document 3 discloses a deep ultraviolet light emitting element structure of a Group III nitride semiconductor having light emission wavelengths of 220 to 280 nm, the deep ultraviolet light emitting element structure including an AlGaN/GaN short period superlattice layer composed of an AlGaN barrier layer and a GaN well layer, an n-type AlGaN functional layer and a p-type AlGaN contact layer that are disposed so as to vertically sandwich the AlGaN/GaN short period superlattice layer, in which the Al composition of the AlGaN barrier layer, the Al composition of the n-type AlGaN layer and the Al composition of the p-type AlGaN layer are 70% or higher and the thickness of the GaN well layer is 0.75 nm or less. Patent Document 3 states that a high light emission efficiency can be obtained since the AlGaN/GaN short period superlattice layer coherently and epitaxially grows, a defect such as a misfit dislocation is not generated and large compressive strain is present in the GaN layer.

For example, Patent Document 4 discloses, in order to realize an efficient ultraviolet LED, a heteroepitaxy strain management structure having a substrate or template, an AlN or AlGaN functional layer that is epitaxially formed on the substrate or template, for which a calculated in-plane compressive strain that is applied to the AlN or AlGaN functional layer by the substrate or template is 1% or more, and a highly doped epitaxial AlN or AlGaN interlayer inserted between the epitaxial AlN or AlGaN functional layer and the substrate or template, in which the highly doped epitaxial AlN or AlGaN interlayer has a thickness of 40 to 400 nm and is doped within a range of 5×10¹⁹ to 5×10²⁰ cm⁻³.

### CITATION LIST

### Patent Document

### Patent Document 1

Japanese Patent No. 4681684

### Patent Document 2

Japanese Patent No. 5274785

### Patent Document 3

Japanese Patent No. 5400001

### Patent Document 4

Japanese Patent No. 6353133

### Non-Patent Document

### Non-Patent Document 1

Y. Nagasawa and A. Hirano, Appl. Sci., 8, 1264 (2018).

### Non-Patent Document 2

Z. Ren et al., Applied Physics Letters 91, 051116 (2007).

### Non-Patent Document 3

J. R. Grandusky et al., Journal of Crystal Growth 311, 2864 (2009).

### Non-Patent Document 4

V. ADIVARAHAN et al., Jpn. J. Appl. Phys., 46, L877 (2007).

### Non-Patent Document 5

X. Li et al., Optical Materials Express, 5, 380 (2015)

### Non-Patent Document 6

J. Enslin et al., Journal of Crystal Growth 464, 185 (2017).

### Non-Patent Document 7

T. Matsumoto et al., J. Phys. D: Appl. Phys. 52, 115102(2019).

### Non-Patent Document 8

M. Ajmal Khan et al., J. Mater. Chem. C, 7, 143, (2019).

### Non-Patent Document 9

M. A. Moram, et al., Rep. Prog. Phys. 72, 036502 (2009).

### SUMMARY OF INVENTION

### Technical Problem

For example, the light emission efficiency (external quantum efficiency) in conventional ultraviolet LEDs for which AlGaN is used does not reach 10%. The external quantum efficiency is determined by the product of the light emission efficiency (internal quantum efficiency), the electron/hole injection efficiency and the light extraction efficiency in a functional layer that configures an LED, and the density of dislocations that are present in crystals is affected by any or all of them. Particularly, in a case where the threading dislocation density exceeds 2×10⁹ cm⁻², it is known that the internal quantum efficiency reaches 40% or lower. Therefore, improvement in the internal quantum efficiency, the electron/hole injection efficiency and the light extraction efficiency is required to realize high-efficiency LEDs. In order for that, a decrease in the threading dislocation density is required. In addition, for example, in the case of an FET for which AlGaN is used, the interface between a functional layer and an active layer needs to be flat at an atomic level.

In order to improve the device characteristics of devices such as LEDs or FETs, it is important that the thickness of a functional layer is approximately 2000 to 4000 nm. However, as described in Non-Patent Documents 2 to 8, in the case of non-coherent growth where the in-plane lattice constant of a Group III semiconductor crystal does not match, when an attempt is made to make the thickness of a functional layer be the above-described thickness, since a misfit dislocation is generated due to lattice relaxation, the threading dislocation density of semiconductor crystals increases to 2×10⁹ cm⁻² or higher, and favorable device characteristics cannot be obtained. In addition, since lattice relaxation makes the surface flatness of the semiconductor crystals significantly poor, it becomes difficult to secure in-plane uniformity in terms of the crystal quality or the sheet resistance in the case of using a large (6 inches or the like) substrate.

Patent Documents 1 to 3 describe that it is ideal to form a pseudomorphic state where coherent growth, in which a substrate and Group III semiconductor crystals coincide with each other in the in-plane lattice constant, occurs and provide structures in which the avoidance of non-coherent growth in which the in-plane lattice constants do not match is intended.

Patent Document 4 describes a structure in which a highly doped interlayer is used for strain management, whereby the in-plane compressive strain is 1% or more. However, whether or not doping improves the surface state of the semiconductor substrate and the threading dislocation density of the functional layer is not disclosed. In addition, in the case of intending to produce a device, for example, an FET, since the doped interlayer may act as a source of a leak current, a drift current or the like, the application of the structure is limited only to a specific use.

An object of the present invention is to provide a compound semiconductor substrate in which, in a functional layer, a region where the lattice is relaxed from the crystal lattice of a lower layer is dominant, the surface state is favorable, and a low threading dislocation density is satisfied at the same time, whereby characteristics required for a device, such as efficiency, are satisfied and the in-plane uniformity of a physical property value, such as sheet resistance, is secured. The details will be described below, but the lower layer mentioned herein refers to a substrate base layer or an interlayer disposed on the surface of a substrate or base layer.

### Solution to Problem

In order to achieve the above-described object, in a first aspect of the present invention, a compound semiconductor substrate having a base layer having an in-plane lattice constant of a, a stress relaxation layer that relaxes strain that is received from the base layer and a functional layer having an in-plane lattice constant of b (a≠b), in which the base layer, the stress relaxation layer and the functional layer are disposed in order of the base layer, the stress relaxation layer and the functional layer, in the functional layer, a region where a lattice is relaxed from a crystal lattice of the base layer is dominant, and a threading dislocation density of the functional layer is lower than 2.0×10⁹ cm⁻², is provided.

In the base layer, the lattice may be fully matched or pseudomorphically matched with respect to a substrate and may be partially relaxed or fully relaxed. In addition, the base layer may be a flat substrate that covers the entire surface of the substrate or a patterned substrate having a partially processed surface.

The stress relaxation layer may be formed so that a part that is not coherent with the base layer becomes dominant, and an in-plane lattice constant may be c that satisfies

$$( a + c - 2 \times b ) / ( 2 \times b ) \leq \pm 0.5 \% .$$

The lattice relaxation ratio of the functional layer with respect to the base layer is preferably within a range of 60% or higher, more preferably within a range of 75% or higher and particularly preferably within a range of 90% or higher.

The threading dislocation density of the functional layer is preferably 1.5×10⁹ cm⁻² or lower and more preferably 1.3×10⁹ cm⁻² or lower. The threading dislocation density of the functional layer is preferably as low as possible, and the lower limit is thus not particularly specified. The threading dislocation density of the functional layer can be set to, for example, 1.0×10² cm⁻² or higher or 1.0×10³ cm⁻² or higher.

A semiconductor crystal layer may further have an interlayer that is positioned in contact with the base layer between the base layer and the stress relaxation layer. The thickness of the semiconductor crystal layer may be 1000 nm or more and 16000 nm or less.

The thickness of the substrate may be 200 μm or more, the diameter of the substrate may be 25 mm or more, the thickness of the base layer may be 50 nm or more and 5000 nm or less, and a surface of the functional layer may be a mirror surface.

In a second aspect of the present invention, a method for inspecting a compound semiconductor substrate having a base layer having an in-plane lattice constant of a, a stress relaxation layer that relaxes strain that is received from the base layer and a functional layer having an in-plane lattice constant of b (a≠b), in which the base layer, the stress relaxation layer and the functional layer are disposed in order of the base layer, the stress relaxation layer and the functional layer, in the functional layer, a region where a lattice is relaxed from a crystal lattice of the base layer is dominant, and a threading dislocation density of the functional layer is lower than 2.0×10⁹ cm⁻², in which not only a case where the lattice relaxation ratio of the functional layer with respect to the base layer by X-ray reciprocal lattice mapping in an asymmetrical plane of the semiconductor crystal layer is 60% or more but also a case where the full width at half maximum of an X-ray rocking curve in a diffraction plane (102) of the functional layer is less than 550 arcsec are judged as pass, is provided. Here, the asymmetrical plane is an X-ray diffraction plane expressed with the Miller indices in the case of, for example, a diffraction plane (−1−14) and refers to the case of h=−1, k=−1, 1=4 in the expression of the plane (hkl) by the Miller indices. An index −1 will be expressed with a symbol of a horizontal line over 1 (bar notation) in some cases.

In a third aspect of the present invention, a compound semiconductor substrate having a base layer having an in-plane lattice constant of a, a stress relaxation layer that relaxes strain that is received from the base layer and a functional layer having an in-plane lattice constant of b (a/b), in which the base layer, the stress relaxation layer and the functional layer are disposed in order of the base layer, the stress relaxation layer and the functional layer, and the stress relaxation layer has a first crystal layer that is positioned in contact with the base layer and has an in-plane lattice constant of c1 that is between a and b and a second crystal layer that is positioned in contact with a functional layer side of the first crystal layer and has an in-plane lattice constant of c2 that satisfies (c1+c2−2×b)/(2×b)≤±0.5%, is provided. Similar to the first aspect, the compound semiconductor substrate may further have an additional configuration. b in the formula in the third aspect is the in-plane lattice constant of the functional layer.

The thickness of the first crystal layer is preferably 6 nm or more and 125 nm or less, more preferably 10 nm or more and 100 nm or less and particularly preferably 20 nm or more and 75 nm or less. With a thickness of 6 nm or more and 125 nm or less, the surface state further improves.

The thickness of the second crystal layer is preferably 6 nm or more and 125 nm or less, more preferably 10 nm or more and 100 nm or less and particularly preferably 20 nm or more and 75 nm or less. With a thickness of 6 nm or more and 125 nm or less, the surface state further improves.

It is preferable that the stress relaxation layer has two or more periods as a repetition count of a laminate structure composed of the first crystal layer and the second crystal layer and the thickness of the stress relaxation layer is 500 nm or more and 10000 nm or less.

In the stress relaxation layer, the chemical composition of the first crystal layer is AlₓGa₁₋ₓN (0<x≤1.0), the chemical composition of the second crystal layer is Al_{y}Ga_{1-y}N (0≤y<1.0), and y<x is satisfied.

The stress relaxation layer may have a plurality of laminate structures composed of the first crystal layer and the second crystal layer. The stress relaxation layer may further have a third crystal layer that is positioned in contact with a functional layer side of the second crystal layer and has an in-plane lattice constant of c3 that satisfies (c1+c2+c3−3×b)/(3×b)≤±0.5%. The stress relaxation layer may further have an n^{th} crystal layer that is positioned in contact with a functional layer side of the n^{th} crystal layer that is positioned on a functional layer side of the third crystal layer and has an in-plane lattice constant of cn that satisfies (c1+c2+ . . . +c(n−1)+cn−n×b)/(n×b)≤±0.5%. Here, n in the formula is an integer of four or higher.

In a fourth aspect of the present invention, a compound semiconductor substrate having a base layer having an in-plane lattice constant of a, a stress relaxation layer that relaxes strain that is received from the base layer, a functional layer having an in-plane lattice constant of b (a≠b) and an active layer having an in-plane lattice constant that pseudomorphically matches the in-plane lattice constant b of the functional layer, in which the base layer, the stress relaxation layer, the functional layer and the active layer are disposed in order of the base layer, the stress relaxation layer, the functional layer and the active layer, in the functional layer, a region where a lattice is relaxed from a crystal lattice of the base layer is dominant, and a threading dislocation density of the functional layer is lower than 2.0×10⁹ cm⁻², is provided. Similar to the third aspect, the compound semiconductor substrate may further have an additional configuration.

The stress relaxation layer may reflect 50% or more of light that is generated from the active layer.

In a fifth aspect of the present invention, a compound semiconductor substrate having a base layer having an in-plane lattice constant of a, a stress relaxation layer that relaxes strain that is received from the base layer, a functional layer having an in-plane lattice constant of b (a≠b), an active layer having an in-plane lattice constant that pseudomorphically matches the in-plane lattice constant b of the functional layer and a contact layer, in which the base layer, the stress relaxation layer, the functional layer, the active layer and the contact layer are disposed in order of the base layer, the stress relaxation layer, the functional layer, the active layer and the contact layer from the substrate side, in the functional layer, a region where a lattice is relaxed from a crystal lattice of the base layer is dominant, and a threading dislocation density of the functional layer is lower than 2.0×10⁹ cm⁻², is provided. Similar to the third aspect, the compound semiconductor substrate may further have an additional configuration.

The contact layer may have a larger band gap than that of the active layer.

The compound semiconductor substrate may have a substrate and a semiconductor crystal layer on the substrate. The semiconductor crystal layer may have at least any layer selected from a base layer having an in-plane lattice constant of a, a stress relaxation layer that relaxes strain that is received from the base layer and a functional layer having an in-plane lattice constant of b (a≠b). In one example, the semiconductor crystal layer may have all of the base layer, the stress relaxation layer and the functional layer. In another example, the semiconductor crystal layer may have the stress relaxation layer and the functional layer. In this case, the substrate is regarded as a base layer in the positional relationship of each layer. Therefore, in a case where the semiconductor crystal layer does not have the base layer, the substrate may be regarded as the base layer in the present invention, and the in-plane lattice constant of the substrate may be regarded as a. In still another example, the semiconductor crystal layer may have the base layer and the stress relaxation layer.

The base layer, the stress relaxation layer and the functional layer may be disposed in order of the base layer, the stress relaxation layer and the functional layer. The stress relaxation layer may have at least any of a first crystal layer that may be positioned in contact with the base layer side and has an in-plane lattice constant of c1 that is between a and b and a second crystal layer that may be positioned in contact with the functional layer side of the first crystal layer and has an in-plane lattice constant of c2 that satisfies (c1+c2−2×b)/(2×b)≤+0.5%. In one example, the stress relaxation layer may have both the first crystal layer and the second crystal layer.

The thickness of the first crystal layer may be 6 nm or more and 125 nm or less. The thickness of the second crystal layer may be 6 nm or more and 125 nm or less. The stress relaxation layer may have two or more periods as a repetition count of lamination composed of the first crystal layer and the second crystal layer. The thickness of the stress relaxation layer may be 500 nm or more and 10000 nm or less. The first crystal layer may be AlₓGa₁₋ₓN (0<x≤1.0), and the second crystal layer may be Al_{y}Ga_{1-y}N (0.1≤y<1.0) (provided that y<x). The stress relaxation layer may have a third crystal layer that may be positioned in contact with a functional layer side of the second crystal layer and has an in-plane lattice constant of c3 that satisfies (c1+c2+c3−3×b)/(3×b)≤±0.5%. The stress relaxation layer may have an n^{th} crystal layer that is positioned in contact with a functional layer side of the n^{th} crystal layer that is positioned in contact with a functional layer side of the third crystal layer and has an in-plane lattice constant of cn that satisfies (c1+c2+ . . . +c(n−1)+cn−n×b)/(n×b)≤±0.5%. Here, n in the formula is an integer of four or higher.

The lattice relaxation ratio of the functional layer with respect to the base layer may be 60% or higher. The threading dislocation density of the functional layer may be lower than 2.0×10⁹ cm⁻². The semiconductor crystal layer may have, between the base layer and the stress relaxation layer, an interlayer that may be positioned in contact with the base layer and has an in-plane lattice constant that is different from the in-plane lattice constant of the base layer. The semiconductor crystal layer may have an active layer that is positioned on the functional layer and has an in-plane lattice constant that pseudomorphically matches the in-plane lattice constant b of the functional layer. The stress relaxation layer may reflect 50% or more of light that is generated from the active layer. The semiconductor crystal layer may have a contact layer that is positioned on the active layer. The contact layer may have a larger band gap than that of the active layer. The thickness of the semiconductor crystal layer may be 1000 nm or more and 16000 nm or less. The thickness of the base layer may be 50 nm or more and 5000 nm or less. The thickness of the substrate may be 200 μm or more. The diameter of the substrate may be 25 mm or more. A surface of the functional layer may be a mirror surface.

In the above-described method for inspecting a compound semiconductor substrate, not only a case where the lattice relaxation ratio of the functional layer with respect to the base layer by X-ray reciprocal lattice mapping of the semiconductor crystal layer is 60% or more but also a case where the full width at half maximum of an X-ray rocking curve in a diffraction plane (102) of the functional layer is less than 550 arcsec may be judged as pass.

### Advantageous Effects of Invention

According to the above-described aspects of the present invention, when a region where the lattice is relaxed from the crystal lattice of a lower layer is dominant in a functional layer, the surface state is favorable, and a low threading dislocation density is satisfied at the same time, it is possible to satisfy characteristics required for a device, such as efficiency, and to secure the in-plane uniformity of a physical property value, such as sheet resistance.

### BRIEF DESCRIPTION OF DRAWINGS

FIG. 1 is a cross-sectional view of a compound semiconductor substrate 100 according to a first embodiment of the present invention.

FIG. 2 is a cross-sectional view showing a modification example of the compound semiconductor substrate 100 according to the same embodiment.

FIG. 3 is a cross-sectional view showing another modification example of the compound semiconductor substrate 100 according to the same embodiment.

FIG. 4 is a cross-sectional view showing still another modification example of the compound semiconductor substrate 100 according to the same embodiment.

FIG. 5 is a cross-sectional view of a compound semiconductor substrate 200 according to a second embodiment of the present invention.

FIG. 6 is a cross-sectional view showing a modification example of the compound semiconductor substrate 200 according to the same embodiment.

FIG. 7 is a cross-sectional view showing a compound semiconductor substrate 300 according to a third embodiment of the present invention.

FIG. 8 is a cross-sectional view showing a compound semiconductor substrate 400 according to a fourth embodiment of the present invention.

FIG. 9 is an X-ray reciprocal lattice mapping image of a diffraction plane (−1-14) that becomes an asymmetrical plane of Experiment Example 4.

FIG. 10 is an atomic force microscope image of a surface of Experiment Example 4 scanned within a 20 μm-square field of view.

FIG. 11 is a graph in which X-ray rocking curves in diffraction planes (002) and (102) of a functional layer 108 of Experiment Example 4 are plotted.

FIG. 12 is a graph in which the lattice relaxation ratios of Experiment Examples 1 to 5, 12 and 13 are plotted.

FIG. 13 is a graph in which the surface roughness of Experiment Examples 1 to 5, 12 and 13 are plotted.

FIG. 14 is a graph in which the dislocation densities of Experiment Examples 1 to 5, 12 and 13 are plotted.

FIG. 15 is a graph in which the lattice relaxation ratios of Experiment Examples 3 and 6 to 10 are plotted.

FIG. 16 is a graph in which the surface roughness of Experiment Examples 3 and 6 to 10 are plotted.

FIG. 17 is a graph in which the dislocation densities of Experiment Examples 3 and 6 to 10 are plotted.

FIG. 18 is an X-ray reciprocal lattice mapping image of a diffraction plane (−1-14) that becomes an asymmetrical plane of Experiment Example 11.

FIG. 19 is an atomic force microscope image of a surface of Experiment Example 11 scanned within a 20 μm-square field of view.

FIG. 20 is a graph in which X-ray rocking curves in diffraction planes (002) and (102) of a functional layer 108 of Experiment Example 11 are plotted.

FIG. 21 is a graph in which the lattice relaxation ratios of Experiment Examples 19 to 26 are plotted.

FIG. 22 is a graph in which the surface roughness of Experiment Examples 19 to 26 are plotted.

FIG. 23 is a graph in which the dislocation densities of Experiment Examples 19 to 26 are plotted.

FIG. 24 is a graph in which the PL intensities of Experiment Examples 19 to 26 are plotted.

FIG. 25 is a graph in which the sheet resistance in-plane distributions of Experiment Examples 19 to 26 are plotted.

FIG. 26 is a graph in which the reflection spectrum of Experiment Example 29 is plotted.

FIG. 27 is a graph in which the reflectance of Experiment Examples 27 to 30 is plotted.

FIG. 28 is a graph in which the X-ray diffraction pattern of Experiment Example 31 is plotted.

### DESCRIPTION OF EMBODIMENTS

### Embodiment 1

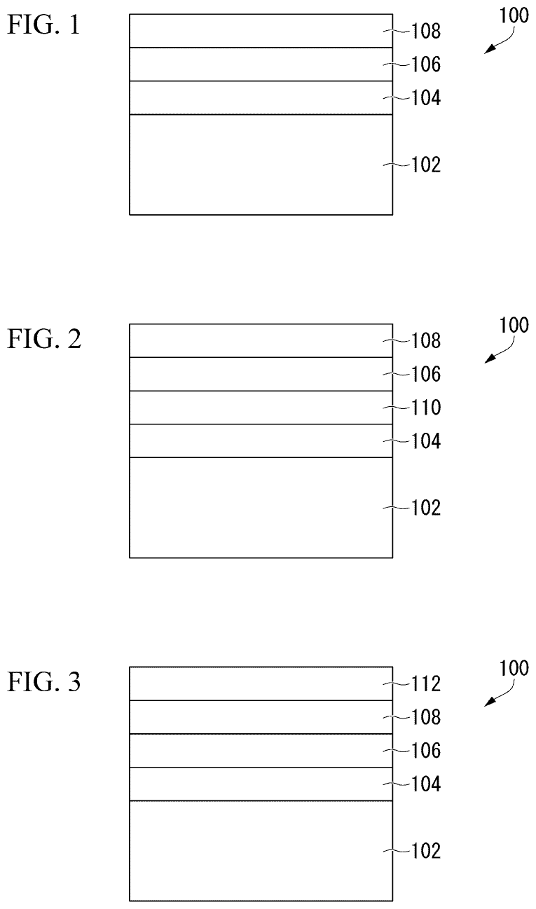

FIG. 1 is a cross-sectional view of a compound semiconductor substrate 100 according to a first embodiment of the present invention. The compound semiconductor substrate 100 has a substrate 102 and a semiconductor crystal layer on the substrate 102. The substrate 102 is a support substrate that supports the semiconductor crystal layer. As the substrate 102, a sapphire, silicon, gallium arsenide, gallium antimony, indium arsenide, gallium oxide, silicon carbide, gallium nitride or aluminum nitride substrate or the like can be used. The use of a large substrate having a diameter of 150 mm or the like as the substrate 102 makes it possible to lower the material price and to industrially enhance the cost competitiveness at a low cost. Therefore, the substrate 102 preferably has a diameter of 150 mm or larger.

The semiconductor crystal layer has a base layer 104, a stress relaxation layer 106 and a functional layer 108, and the base layer 104, the stress relaxation layer 106 and the functional layer 108 are disposed in order of the base layer 104, the stress relaxation layer 106 and the functional layer 108 from the substrate 102 side.

The base layer 104 has an in-plane lattice constant a, and the chemical composition of the base layer 104 can be, for example, Alₓ₁Ga₁₋ₓN (0.8≤x1≤1.0) and, typically, can be AlN (x1=1). The base layer 104 makes it possible to form an initial nucleus on the substrate 102 and to improve the flatness of the semiconductor crystal layer.

In the compound semiconductor substrate 100 according to the present embodiment, the first semiconductor layer of the semiconductor crystal layer on the substrate 102 is the base layer 104, and the crystal characteristics of this base layer 104 significantly affect the crystal characteristics of the semiconductor crystal layer that grows thereon.

The stress relaxation layer 106 is, for example, Alₓ₃Ga₁₋ₓ3N, and the composition ratio x3 of Al needs to be determined so that an in-plane lattice constant c of the stress relaxation layer 106 satisfies (a+c−2×b)/(2×b)≤±0.5%. The stress relaxation layer 106 is formed such that a part that is not coherent with the base layer 104 becomes dominant and plays a role of relaxing strain that is received from the base layer 104, whereby the crystallinity of the functional layer 108, which is a nitride semiconductor layer, that is formed on the stress relaxation layer 106 improves, and the electrical, optical, mechanical and chemical characteristics of the functional layer 108 improve. That is, the threading dislocation density of the functional layer 108 in which stress has been relaxed is reduced, and the crystal quality can be improved.

In order to improve the crystal quality of a nitride semiconductor layer, it is common to form the nitride semiconductor layer so as to be coherent with the crystal lattice of a base in a heterojunction surface. However, in a case where the base layer 104 and the stress relaxation layer 106 are formed such that a non-coherent part becomes dominant as in the present invention, since each has a different in-plane lattice constant in the crystal, stress stain is further accumulated in a film as the thickness becomes thicker, and when the grown thickness exceeds a critical thickness, a large number of defects are generated to relax the strain. If growth continues after the large number of defects are generated, the film grows in a three-dimensional manner, and there are cases where the surface is thus not a mirror surface, and the compound semiconductor substrate becomes white turbid in the end. In this case, the crystal quality of the functional layer 108 formed on the stress relaxation layer 106 is significantly impaired.

The present inventors studied and consequently found that, even when a misfit dislocation is generated due to a non-coherently-formed interface, it is possible to obtain a low threading dislocation density and a sufficient crystal quality depending on the formation conditions of the stress relaxation layer 106. The details of the mechanism are not clear, but the present inventors presume that the reason therefor is the annihilation of dislocations in the stress relaxation layer 106, which prevents propagation of the dislocation into the functional layer 108 formed over the stress relaxation layer 106.

It is known that lattice relaxation varies with the laminate structure (lattice constant difference or thickness) of the semiconductor crystal layer, the crystal quality (threading dislocation density) or the growth conditions; however, according to the present embodiment, the lattice relaxation ratio can be controlled by the formation of the stress relaxation layer 106 described above.

When stress is sufficiently relaxed by the stress relaxation layer 106, the lattice relaxation ratio of the functional layer 108 with respect to the base layer 104 is high, the surface flatness is excellent, and a low threading dislocation density can be realized. In addition, when stress in the entire wafer is relaxed, it is possible to suppress an in-plane variation in a physical property value such as the sheet resistance at a low level. That is, the uniformity of the semiconductor crystal layer that is formed on the substrate 102 can be enhanced.

The functional layer 108 is composed of Alₓ₄Ga₁₋ₓ4N (0≤x4<1) and is typically a layer that satisfies (0.3≤x4≤0.7). The functional layer 108 is a layer on which a photoelectric element is to be formed in the future. In the functional layer 108, a region where the lattice is relaxed from the crystal lattice of the base layer 104 is dominant. For example, in the functional layer 108, the lattice relaxation ratio of the functional layer 108 with respect to the base layer 104 by the X-ray reciprocal lattice mapping in an asymmetrical diffraction plane is preferably 60% or higher.

The functional layer 108 can be divided into a plurality of (two or more) layers depending on the purpose. For example, in a case where the functional layer 108 is determined to be used as an n-type carrier injection layer to make the functional layer 108 play a role of controlling electrical conduction, for example, a layer in which the flatness is enhanced to reduce the scattering of carriers is provided on the side of the functional layer 108 in contact with the stress relaxation layer 106, and an electrical conduction layer in which the concentration of an impurity, such as carbon, that acts as an n-type carrier compensation is extremely lowered is provided as an upper layer of the previous layer, whereby the sheet resistance of the entire device can be decreased. Alternatively, when a high-resistance layer in which the voltage resistance is enhanced is provided on the side of the functional layer 108 in contact with the stress relaxation layer 106, and a high-purity layer in which the concentration of an impurity is extremely lowered is provided as an upper layer thereof for the purpose of using the functional layer 108 as an electron transport layer, it is possible to suppress the scattering of carriers and increase the electron mobility.

The thickness of the semiconductor crystal layer, in other words, the total thickness of the base layer 104, the stress relaxation layer 106 and the functional layer 108 is preferably set to 500 nm or more and 16000 nm or less. When the thickness of the semiconductor crystal layer is set within the above-described range, it is possible to decrease the amount of warpage of the compound semiconductor substrate 100. In a case where the thickness of the substrate 102 is 200 μm or more and the diameter of the substrate 102 is 25 mm or more, the thickness of the base layer 104 is preferably set to 50 nm or more and 5000 nm or less. When the substrate 102 and the base layer 104 are set within the above-described ranges, it is possible to decrease the amount of warpage of the compound semiconductor substrate 100. The thickness of the functional layer 108 is more preferably 2000 nm or more and 4000 nm or less. When the thickness of the functional layer 108 is set within the above-described range, it is possible to further improve device characteristics. In a case where the semiconductor crystal layer does not have the base layer 104, the thickness of the semiconductor crystal layer is the total thickness of the stress relaxation layer 106 and the functional layer 108.

When the temperatures of a semiconductor crystal layer and the substrate 102 lower from a high temperature during epitaxial growth to room temperature, stress is generated in the semiconductor crystal layer with respect to the substrate 102 due to the difference in the thermal expansion coefficient from the substrate 102. However, in the compound semiconductor substrate 100 of the present embodiment, since stress is relaxed by the stress relaxation layer 106, it is possible to suppress warpage of the compound semiconductor substrate 100.

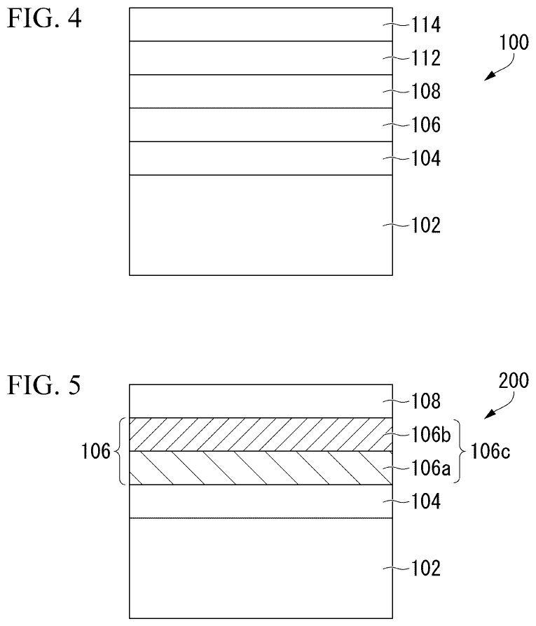

An arbitrary layer may be disposed in at least any position of between the base layer 104 and the stress relaxation layer 106, between the stress relaxation layer 106 and the functional layer 108 and in an upper layer of the functional layer 108. For example, an interlayer 110 may be formed between the base layer 104 and the stress relaxation layer 106 as shown in FIG. 2, for example, an active layer 112 may be formed on the functional layer 108 as shown in FIG. 3, and for example, the active layer 112 and a contact layer 114 may be formed on the functional layer 108 as shown in FIG. 4. The interlayer 110, the active layer 112 and the contact layer 114 are, similar to the base layer 104, the stress relaxation layer 106 and the functional layer 108, layers that configure the semiconductor crystal layer. Therefore, in a case where the semiconductor crystal layer has these layers, the thickness of the semiconductor crystal layer is the total thickness also including the thicknesses of these layers.

The interlayer 110 in the configuration of FIG. 2 is disposed between the base layer 104 and the stress relaxation layer 106 in contact with the base layer 104. The chemical composition of the interlayer 110 is composed of, for example, Alₓ₂Ga₁₋ₓ2N (0.6≤x2≤0.9). The interlayer 110 enlarges the initial nucleus formed in the base layer 104 and forms a base surface of the stress relaxation layer 106 that is formed on the upper of the interlayer 110. The hetero interface between the interlayer 110 and the base layer 104 may be coherently continuous or a non-coherently grown region may be dominant.

As the active layer 112 in the configuration of FIG. 3, it is possible to form a Schottky layer having a chemical composition of Alₓ₅Ga₁₋ₓ5N. In detail, in the hetero interface between the active layer 112 and the functional layer 108, a two-dimensional electron gas (2DEG) is generated, and a Schottky layer, which functions as an electron supply layer of a transistor, can be formed. The Al composition ratio x5 of the active layer 112 needs to be higher than the Al composition ratio x3 of the functional layer 108, and the thickness needs to be determined within a range where the lattice pseudomorphically matches b, which is the in-plane lattice constant of the functional layer 108, and can be changed as appropriate depending on the structure of a transistor to be formed.

As the active layer 112 in the configuration of FIG. 4, it is possible to form, for example, a multiple quantum well (MQW) layer in which a light emitting region is composed of Alₓ₆Ga₁₋ₓ6N/Alₓ₇Ga₁₋ₓ7N. The Al compositions x6 and x7 and each thickness of the MQW layer need to be determined within a range where the lattice pseudomorphically matches b, which is the in-plane lattice constant of the functional layer 108, and can be changed as appropriate depending on the structure of a diode to be formed.

As the contact layer 114, it is possible to form, for example, Mg-doped Alₓ₈Ga₁₋ₓ₈N, and the Al composition x8 and thickness thereof can be changed as appropriate depending on the structure of a diode to be formed. In addition, the contact layer 114 may be composed of boron nitride (BN) having a large band gap.

### Embodiment 2

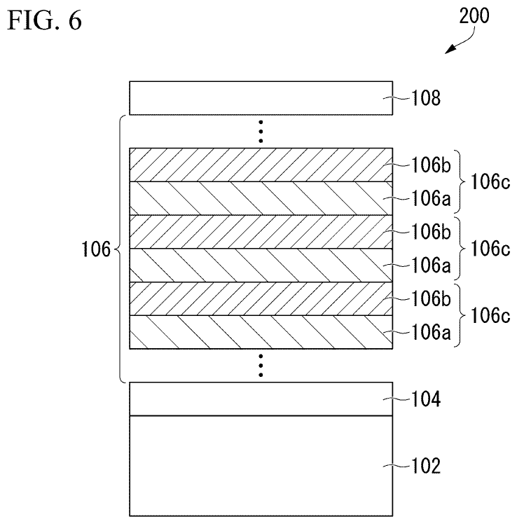

FIG. 5 is a cross-sectional view of a compound semiconductor substrate 200 according to a second embodiment of the present invention. FIG. 6 is a cross-sectional view showing a modification example of the compound semiconductor substrate 200. As shown in FIG. 5, the compound semiconductor substrate 200 has, similar to the compound semiconductor substrate 100, a semiconductor crystal layer on a substrate 102, and the semiconductor crystal layer has a base layer 104, a stress relaxation layer 106 and a functional layer 108. However, the stress relaxation layer 106 in the compound semiconductor substrate 200 has one or a plurality of laminate structures 106c as shown in FIG. 5 and FIG. 6. The laminate structure 106c has a first crystal layer 106a and a second crystal layer 106b. The other configurations of the compound semiconductor substrate 200 are the same as those of the compound semiconductor substrate 100.

The first crystal layer 106a has an in-plane lattice constant of c1 that is between a and b, and the thickness is preferably 6 nm or more and 125 nm or less. The second crystal layer 106b has an in-plane lattice constant of c2 that satisfies (c1+c2−2×b)/(2×b)≤±0.5%, and the thickness is preferably 6 nm or more and 125 nm or less, is provided. The first crystal layer 106a and the second crystal layer 106b are disposed in this order from the substrate 102 side.

The first crystal layer 106a is composed of, for example, AlₓGa₁₋ₓN (0<x≤1.0), which is typically 0.6<x≤0.9. When the thickness of the first crystal layer 106a is set to 6 nm or more, it is possible to maintain the flatness of the stress relaxation layer 106. When the thickness of the first crystal layer 106a is made to be too small, the surface flatness is impaired, and, when the thickness of the first crystal layer 106a is made to be too large, there is a tendency that the stress relaxation effect is impaired, and the thickness of the first crystal layer 106a is preferably 6 nm or more and 125 nm or less, more preferably 10 nm or more and 100 nm or less and particularly preferably 20 nm or more and 75 nm or less.

The second crystal layer 106b is composed of, for example, Al_{y}Ga_{1-y}N (0≤y<1.0), which is typically (0.1≤y≤0.6). Here, y is a value smaller than the Al composition ratio x of the first crystal layer 106a. The thickness of the second crystal layer 106b can be set to 6 nm or more and 125 nm or less. When the thickness of the second crystal layer 106b is made to be too small, the stress relaxation effect is impaired, and, when the thickness of the second crystal layer 106b is made to be too large, there is a tendency that the surface flatness is impaired, and the thickness of the second crystal layer 106b is preferably 6 nm or more and 125 nm or less, more preferably 10 nm or more and 100 nm or less and particularly preferably 20 nm or more and 75 nm or less. The second crystal layer 106b is intentionally formed so that the crystal lattice is not coherent with the crystal lattice of the first crystal layer 106a in the heterojunction surface with the first crystal layer 106a. Since the in-plane lattice constant c2 of the second crystal layer 106b in a bulk state is different from the in-plane lattice constant c1 of the first crystal layer 106a in a bulk state as described above, when the second crystal layer 106b is not coherent with the first crystal layer 106a, stress with respect to the first crystal layer 106a is released in the second crystal layer 106b. This accelerates stress relaxation.

The plurality of laminate structures 106c may configure a multilayer laminate structure, that is, a superlattice structure as shown in FIG. 6. The repetition period count of the laminate structures 106c (the number of the laminate structures 106c laminated) can be set to, for example, one to 100. When the stress relaxation layer 106 is provided with a laminate structure having a large repetition period count, it is possible to enhance the stress relaxation effect of the stress relaxation layer 106. In addition, the lattice relaxation ratio of the stress relaxation layer 106 can be easily controlled by the number of the laminate structures 106c laminated.

Therefore, the hetero interface between the first crystal layer 106a and the second crystal layer 106b is considered to be not an ideal coherent interface but an interface where defects are actively and partially provided and the lattice is relaxed by the defect parts, and it is considered that the lamination of the hetero interfaces between the first crystal layer 106a and the second crystal layer 106b makes a non-coherent part more dominant.

It is expected that, as the thickness of the stress relaxation layer 106, particularly, the thickness of the second crystal layer 106b increases, and as the repetition period count of the first crystal layer 106a and the second crystal layer 106b increases, strain is further relaxed, that is, the lattice relaxation ratio of the functional layer 108 with respect to the base layer 104 becomes higher. In the present embodiment, the lattice relaxation ratio becomes high, and effects of improvement in the full width at half maximum of the X-ray rocking curve of the functional layer 108 in a diffraction plane (102) and, furthermore, the surface being a mirror surface can be obtained at the same time. Here, “the surface being mirror surface” refers to the fact that there is no white turbidity under normal fluorescent lighting (1000 to 5000 lux). The mechanism of these characteristic parameters improving in a balanced manner is not clear, but the present inventors presume that the threading dislocation density of the base layer 104 and conditions such as the growth temperatures or the like of the stress relaxation layer 106 and the functional layer 108 have an influence thereon.

As long as the stress relaxation layer 106 includes the laminate structure 106c composed of the first crystal layer 106a and the second crystal layer 106b, the other layer configurations of the stress relaxation layer 106 are arbitrary. For example, a crystal layer that configures the stress relaxation layer 106 may be a so-called graded crystal layer in which the composition continuously changes in the depth direction.

### Embodiment 3

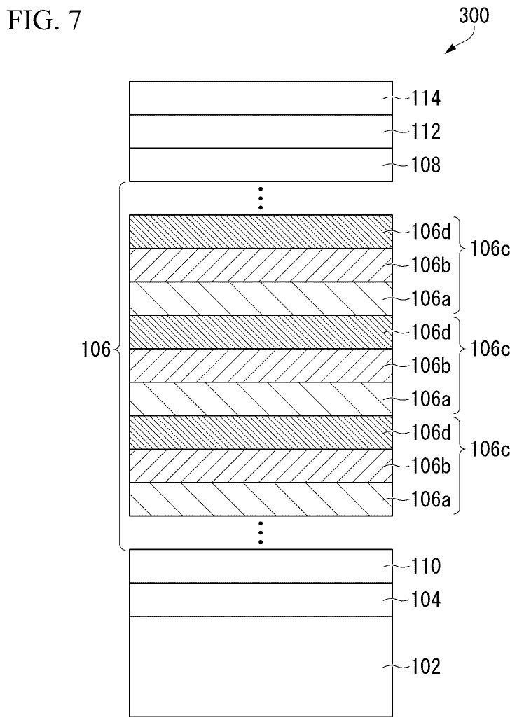

FIG. 7 is a cross-sectional view showing a compound semiconductor substrate 300 according to a third embodiment. The compound semiconductor substrate 300 has, similar to the compound semiconductor substrate 100, a semiconductor crystal layer on a substrate 102, and the semiconductor crystal layer has a base layer 104, a stress relaxation layer 106 and a functional layer 108. However, the stress relaxation layer 106 in the compound semiconductor substrate 300 further has a third crystal layer 106d having an in-plane lattice constant of c3 that satisfies (c1+c2+c3−3×b)/(3×b)≤±0.5% in the stress relaxation layer 106 of the second embodiment. The first crystal layer 106a, the second crystal layer 106b and the third crystal layer 106d are disposed in this order from the substrate 102 side. The other configurations of the compound semiconductor substrate 300 are the same as those of the compound semiconductor substrate 100. FIG. 7 shows an aspect in which a plurality of laminate structures 106c are laminated, but the compound semiconductor substrate 300 may have one laminate structure 106c. In other words, the repetition period count of the laminate structure 106c in the compound semiconductor substrate 300 may be one.

The third crystal layer 106d is a layer that is composed of, for example, Al_{z1}Ga_{1-z1}N(0)≤z1≠1) and typically satisfies 0.0≤z1≤0.5. When the thickness of the third crystal layer 106d is arbitrary. However, the in-plane lattice constant of the third crystal layer 106d in a bulk state is set to c3 that satisfies (c1+c2+c3−3×b)/(3×b)≤±0.5%. The third crystal layer 106d is formed so that the crystal lattice is coherently or non-coherently continuous from the crystal lattice of the second crystal layer 106b in the hetero interface with the second crystal layer 106b. In addition, in a case where a plurality of the laminate structures 106c are disposed, the third crystal layer 106d is formed so that the crystal lattice is coherently or non-coherently continuous from the crystal lattice of the first crystal layer 106a in the hetero interface with the first crystal layer 106a. Therefore, stress is further relaxed by the first crystal layer 106a, the second crystal layer 106b and the third crystal layer 106d.

The fact that the hetero interface between the third crystal layer 106d and the 25 second crystal layer 106b and the hetero interface between the third crystal layer 106d and the first crystal layer 106a are coherently or non-coherently continuous refers to the fact that a pseudomorph or lattice relaxation by a defect or the like has occurred, a coherently or non-coherently grown region may be present in a mixed form.

### Embodiment 4

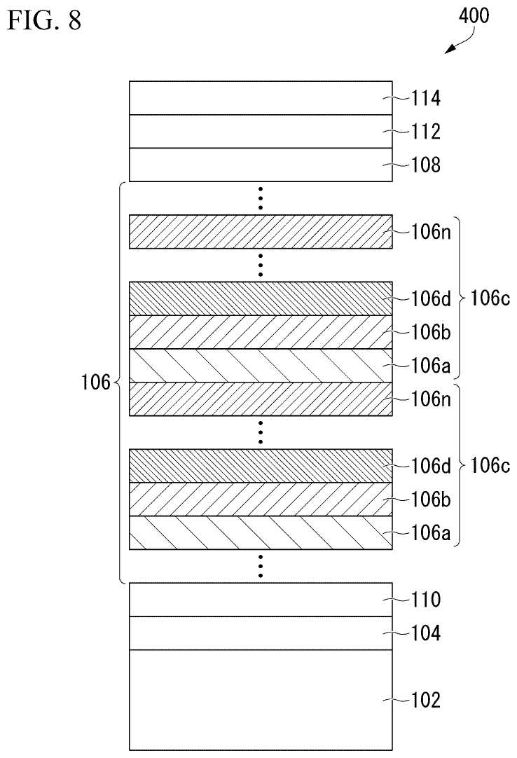

FIG. 8 is a cross-sectional view showing a compound semiconductor substrate 400 according to a fourth embodiment. The compound semiconductor substrate 400 has, similar to the compound semiconductor substrate 100, a semiconductor crystal layer on a substrate 102, and the semiconductor crystal layer has a base layer 104, a stress relaxation layer 106 and a functional layer 108. However, a laminate structure 106c in the stress relaxation layer 106 of the compound semiconductor substrate 400 may have one or more crystal layers that are positioned on the functional layer 108 side of the third crystal layer 106d. The in-plane lattice constant of an n^{th} crystal layer 106n that is a crystal layer positioned closest to the functional layer 108 in the laminate structure 106c is cn that satisfies (c1+c2+ . . . +c (n−1)+cn−n×b)/(n×b)≤±0.5%. In other words, cn is the in-plane lattice constant of an n^{th} crystal layer (n^{th} crystal layer 106n) that is counted from the first crystal layer 106a. Here, n is an integer of four or higher. The other configurations of the compound semiconductor substrate 400 are the same as those of the compound semiconductor substrate 300. In a case where there is one crystal layer that is positioned on the functional layer 108 side of the third crystal layer 106d, in other words, in a case where only a fourth crystal layer 106e is disposed in contact with the third crystal layer 106d in the compound semiconductor substrate 300, the first crystal layer 106a, the second crystal layer 106b, the third crystal layer 106d and the fourth crystal layer 106n are configured to be sequentially laminated together. FIG. 8 shows an aspect in which a plurality of the laminate structures 106c are laminated, but the compound semiconductor substrate 400 may have one laminate structure 106c. In other words, the repetition period count of the laminate structure 106c in the compound semiconductor substrate 400 may be one.

The n^{th} crystal layer 106n is a layer that is composed of, for example, Al_{z2}Ga_{1-z2}N (0≤z2≠1) and typically satisfies 0.0≤z2≤0.5. The thickness of the n^{th} crystal layer 106n is arbitrary. However, the in-plane lattice constant of the n^{th} crystal layer 106n is set to cn that satisfies (c1+c2+ . . . +c(n−1)+cn−n×b)/(n×b)≤±0.5%. The n^{th} crystal layer 106n is formed so that the crystal lattice is coherently or non-coherently continuous from the crystal lattice of an n−1th crystal layer 106(n−1) in the hetero interface with the n−1^{th} crystal layer 106(n−1). Therefore, stress is further relaxed by the first crystal layer 106a, the second crystal layer 106b, the third crystal layer 106d to the n−1th crystal layer 106(n−1) and the n^{th} crystal layer 106n.

The fact that the hetero interface between the n^{th} crystal layer 106n and the n−1th crystal layer 106(n−1) is coherently or non-coherently continuous refers to the fact that a pseudomorph or lattice relaxation by a defect or the like has occurred, a coherently or non-coherently grown region may be present in a mixed form.

The configuration of each layer described in Embodiments 1 to 4 can be arbitrarily combined as long as the combination does not contradict the gist of the invention. In addition, the composition and disposition in the layer of each crystal layer described in Embodiments 1 to 4 are arbitrary as long as the clearly specified condition is satisfied. For example, the composition distribution in the thickness direction in each crystal layer may be uniform or may change in a graded manner. In addition, the thickness of each crystal layer described in Embodiments 1 to 4 is arbitrary as long as the clearly specified condition is satisfied. A combination of the composition distribution and thickness in each crystal layer can also be arbitrarily combined as long as the clearly specified condition is satisfied.

In addition, in Embodiments 2 to 4 as well, similar to Embodiment 1, the compound semiconductor substrate may further have at least any of the interlayer 110, the active layer 112 or the contact layer 114.

Each semiconductor crystal layer described in Embodiments 1 to 4 can be formed by a common epitaxial growth method, for example, a metal organic chemical vapor deposition (MOCVD) method or a hydride vapor phase epitaxy (HVPE) method. For example, regarding a raw material gas, a manufacturing device and a manufacturing conditions such as the film formation temperature that are used in the MOCVD method, well-known material, device and condition can be applied. In a method for manufacturing the compound semiconductor substrates 100 to 400, it is possible to determine the thickness D of the stress relaxation layer 106 according to a formula shown in the following formula (1) and to form the stress relaxation layer 106 in the determined thickness D.

$$500 \leq D = ( d 1 + d 2 + … + d ( n - 1 ) + dn ) \times P \leq 10000 nm ( nm ) \qquad Formula ( 1 )$$

Here, d1, d2, . . . , d(n−1) and dn in the formula (1) are each the thickness of the first crystal layer 106a, the thickness of the second crystal layer 106b, . . . , the thickness of the n−1th crystal layer 106(n−1) and the thickness of the n^{th} crystal layer 106n, and P is the repetition period count. According to the method, it is possible to manufacture the compound semiconductor substrates 100 to 400 having a large lattice relaxation ratio, favorable surface roughness and a low threading dislocation density.

In Embodiments 1 to 4 described above, in the heterojunction surface between a lower layer crystal layer that is positioned on the substrate 102 side of the stress relaxation layer 106 (or the first crystal layer 106a in a case where the stress relaxation layer 106 includes the laminate structure 106c) and the stress relaxation layer 106 or the first crystal layer 106a, a state where the crystal lattice of the stress relaxation layer 106 or the first crystal layer 106a is not coherently continuous from the crystal lattice of the lower layer crystal layer and, while a coherent region and a lattice-relaxed region are present in a mixed form in the interface, the lattice-relaxed region is dominant is preferable. The lower layer crystal layer mentioned herein refers to a crystal layer disposed in contact with the stress relaxation layer 106 or the first crystal layer 106a on the substrate side of the stress relaxation layer 106 or the first crystal layer 106a. Specifically, the lower layer crystal layer refers to the base layer 104, the interlayer 110 (refer to FIG. 2), the second crystal layer 106b (refer to FIG. 6), the third crystal layer 106d (refer to FIG. 7) or the n^{th} crystal layer 106n (refer to FIG. 8) that are in contact with the stress relaxation layer 106 or the first crystal layer 106a. Furthermore, in a case where the base layer 104 and the interlayer 110 are not provided, the substrate 102 in contact with the stress relaxation layer 106 or the first crystal layer 106a corresponds to the lower layer crystal layer.

In addition, in Embodiments 1 to 4 described above, the in-plane lattice constant of each crystal layer, which configures the semiconductor crystal layer, represented by, for example, AlₓGa₁₋ₓN (0<x<1) can be controlled with the Al composition ratio x. In addition, non-coherent growth in the heterojunction surface can be controlled with a process condition such as the growth temperature.

### Embodiment 5

In Embodiments 1 to 4, the characteristics of the present invention have been ascertained as the compound semiconductor substrates 100 to 400, but the characteristics of the present invention can also be ascertained as an inspection method. That is, the characteristics of the present invention can be ascertained as a method for inspecting a compound semiconductor substrate having a substrate 102 and a semiconductor crystal layer on the substrate 102, the semiconductor crystal layer having a base layer 104, a stress relaxation layer 106 that relaxes stress and a functional layer 108 that controls a carrier, and the base layer 104, the stress relaxation layer 106 and the functional layer 108 being disposed in order of the base layer 104, the stress relaxation layer 106 and the functional layer 108 from the substrate 102 side, in which not only a case where the lattice relaxation ratio of the functional layer 108 with respect to the base layer 104 by X-ray reciprocal lattice mapping in an asymmetrical plane of the semiconductor crystal layer is 60% or more but also a case where the full width at half maximum of an X-ray rocking curve in a diffraction plane (102) of the functional layer is less than 550 arcsec are judged as pass. The compound semiconductor substrate, which is an inspection subject, may have an interlayer 110, an active layer 112 and a contact layer 114. In the inspection method according to the present embodiment, the threshold value of the lattice relaxation ratio that is used in the judgement of pass or fail is not limited to 60% and may be changed.

### EXAMPLES

Next, examples of the present invention will be shown, but conditions in the examples are simply examples of the conditions adopted to confirm the feasibility and effect of the present invention, and the present invention is not limited to the conditions used in the following examples. In the present invention, a variety of conditions can be adopted within the scope of the gist of the present invention as long as the object of the present invention is achieved.

### Example 1

An AlN template was prepared by forming AlN in a thickness of 300 to 400 nm as a base layer on a sapphire substrate (size: 50 mm in diameter), and a stress relaxation layer and a functional layer were sequentially formed thereon by a MOCVD method. As the laminate structure of the stress relaxation layer, a 6 to 100 nm-thick Al_{0.8}Ga_{0.2}N layer as a first crystal layer and a 6 to 125 nm-thick Al_{0.5}Ga_{0.5}N layer as a second crystal layer were formed. The second crystal layer was formed on a surface of the first crystal layer opposite to the base layer-side surface. The laminate structure was repeated 1.5 to 50 times and laminated, and each thickness and the repetition count were adjusted so that the total thickness of the stress relaxation layer reached approximately 600 nm. As the functional layer, a 2500 nm-thick Si-doped n-type Al_{0.62}Ga_{0.38}N layer was formed. The growth temperature was changed to be within a range of 1000° C. to 1150° C. Compound semiconductor substrates of Experiment Examples 1 to 10 were produced as described above.

### Comparative Example 1A

An AlN template was prepared by forming AlN in a thickness of 300 to 400 nm as a base layer on a sapphire substrate (size: 50 mm in diameter), and a functional layer was sequentially formed thereon by a MOCVD method. As the functional layer, a 2500 nm-thick Si-doped n-type Al_{0.62}Ga_{0.38}N layer was formed. The growth temperature was changed to be within a range of 1000° C. to 1150° C. A compound semiconductor substrate of Experiment Example 11 was produced as described above. Conditions were set in the same manner as in Example 1 except that the stress relaxation layer was not formed.

### Comparative Example 1B

An AlN template was prepared by forming AlN in a thickness of 300 to 400 nm as a base layer on a sapphire substrate (size: 50 mm in diameter), and a stress relaxation layer and a functional layer were sequentially formed thereon by a MOCVD method. As the laminate structure of the stress relaxation layer, an Al_{0.8}Ga_{0.2}N layer as a first crystal layer and an Al_{0.5}Ga_{0.5}N layer as a second crystal layer were formed, and the repetition count of the laminate structure were adjusted so that the total thickness of the stress relaxation layer reached approximately 600 nm. As the functional layer, a 2500 nm-thick Si-doped n-type Al_{0.62}Ga_{0.38}N layer was formed on the surface of the stress relaxation layer. The growth temperature was changed to be within a range of 1000° C. to 1150° C. Compound semiconductor substrates of Experiment Examples 12 and 13 were produced in combinations of (first crystal layer/second crystal layer/repetition count of laminate structure) of (3 nm/3 nm/100) and (200 nm/200 nm/1.5).

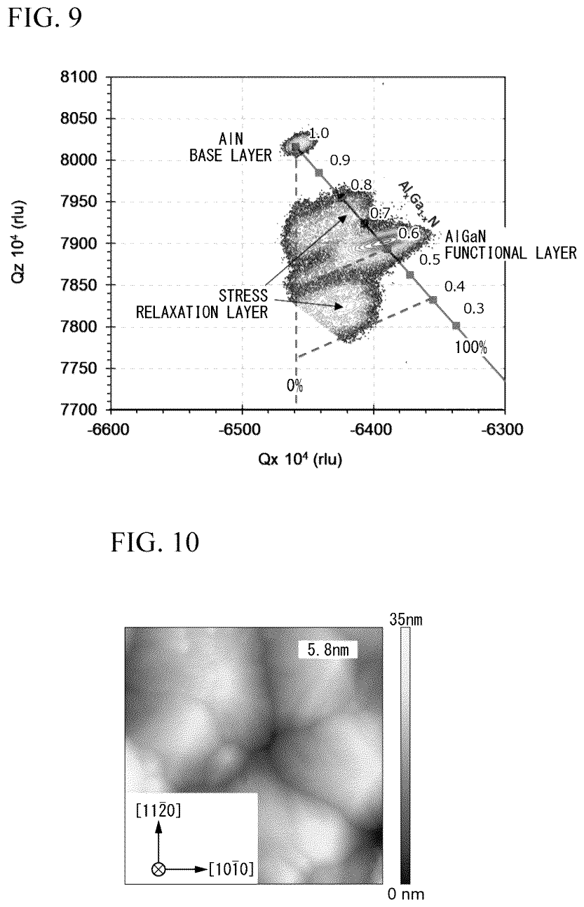

Here, methods for evaluating the lattice relaxation ratio, the surface roughness and the full widths at half maximum of X-ray rocking curves in diffraction planes (002) and (102) will be described using FIG. 9 to FIG. 11 and the compound semiconductor substrate of Experiment Example 4 (the thickness of the first crystal layer was 50 nm, the thickness of the second crystal layer was 50 nm and the repetition period count was six) as an example.

A graph in FIG. 9 is an X-ray reciprocal lattice mapping image of a diffraction plane (−1-14) that becomes an asymmetrical plane of the semiconductor substrate. The positional relationship of each peak in the X-ray reciprocal lattice plane (Qx-Qz plane) of the base layer or the functional layer can be read from FIG. 9. Qz corresponds to the reciprocal of a lattice constant perpendicular to a growth plane, and Qx corresponds to the reciprocal of a lattice constant in a parallel direction to the growth plane. The Qx value and the Qz value becoming small mean the lattice constants becoming large. The in-plane lattice constant a of the base layer being 0.30964 nm can be calculated from the Qx value of the base layer, the in-plane lattice constant b of the functional layer being 0.3132 nm can be calculated from the Qx value of the functional layer, and the composition ratio of Al being 0.62 can be calculated from the Qx value and the Qz value. An in-plane lattice constant r of 0.3132 nm at which the lattice is fully relaxed is calculated from this Al composition ratio, and, when the lattice relaxation ratio R is calculated according to a formula R=|(b−a)/(r−a)|×100, a result of the lattice relaxation ratio being 100% is obtained. That is, in Experiment Example 4, the lattice of the functional layer was fully relaxed with respect to the base layer. The Qx value, the Qz value, the Al composition and the lattice relaxation ratio can be determined with analysis software Epitaxy (version 4.5a) manufactured by Malvern Panalytical Ltd.

FIG. 10 is an atomic force microscope (AFM) image of a surface of the compound semiconductor substrate of Experiment Example 4, in other words, a surface of the functional layer, scanned within a 20 μm-square field of view. The surface roughness was calculated as a roughness of root mean square (RMS) value, and this drawing showed that the surface roughness was as favorable as 5.8 nm and no large holes or steps were observed.

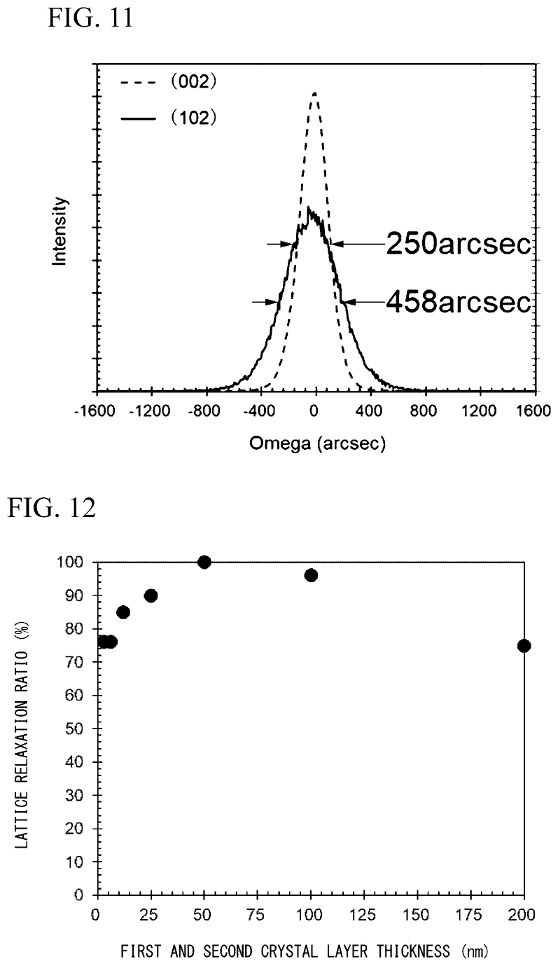

A graph in FIG. 11 shows X-ray rocking curves in diffraction planes (002) and (102) of the functional layer of the compound semiconductor substrate of Experiment Example 4, and it is possible to estimate the respective full widths at half maximum of 250 arcsec and 458 arcsec from FIG. 11. The screw threading dislocation density and the edge threading dislocation density were calculated according to the following formula described in Non Patent Document 9 (M. A. Moram, et al., Rep. Prog. Phys. 72, 036502 (2009).), and the threading dislocation density (the total of the screw threading dislocation density and the edge threading dislocation density) of the functional layer was calculated to be 1.3×10⁹ cm⁻². Hereinafter, the total threading dislocation density of the screw threading dislocation density and the edge threading dislocation density will be simply referred to as the threading dislocation density in some cases.

$$Formula ( 2 )$$

$$Screw threading dislocation density = ( {β}_{( 002 )}^{2} / 3600 \times 2 π / 360 ) / ( 4.35 \times {( 0.508 / {10}^{7} )}^{2} ) ( {cm}^{- 2} )$$

$$Formula ( 3 )$$

$$Edge threading dislocation density = ( {β}_{( 102 )}^{2} / 3600 \times 2 π / 360 ) / ( 4.35 \times {( 0.3132 / {10}^{7} )}^{2} ) ( {cm}^{- 2} )$$

Threading dislocation density=screw threading dislocation density+edge threading dislocation density (cm⁻²)

β₍₀₀₂₎ in the formula (2) is the full width at half maximum (arcsec) of the X-ray rocking curve in the diffraction plane (002), and β₍₁₀₂₎ in the formula (3) is the full width at half maximum (arcsec) of the X-ray rocking curve in the diffraction plane (102). According to this calculation, in Experiment Example 4, the screw threading dislocation density and the edge threading dislocation density each became 0.1×10⁹ cm⁻² or 1.1×10⁹ cm⁻², and the threading dislocation density was estimated to be 1.3×10⁹ cm⁻².

For the compound semiconductor substrates of Experiment Examples 1 to 13, the lattice relaxation ratios, the surface roughness, the full widths at half maximum of the X-ray rocking curves in the diffraction planes (002) and (102) and the dislocation densities were evaluated. The results are shown in Table 1. A case where the lattice relaxation ratio was 60% or higher and the full width at half maximum of the X-ray rocking curve in the diffraction plane (102) of the functional layer was less than 550 arcsec was regarded as pass (A), and a case where at least any of the lattice relaxation ratio of 60% or higher and the full width at half maximum of less than 550 arcsec was not satisfied was regarded as fail (B).

TABLE 1

| | | | | | | | | | | | Threading | |
|---|---|---|---|---|---|---|---|---|---|---|---|---|
| | First | Second | | Stress | | | 002 Full | 102 Full | Screw | Edge | dislo- | |
| | crystal | crystal | Repe- | relaxation | Lattice | | width at | width at | dislo- | dislo- | cation | |
| | layer | layer | tition | layer | relaxation | Surface | half | half | cation | cation | density | |
| | thickness | thickness | period | thickness | ratio | roughness | maximum | maximum | 10⁹ | 10⁹ | 10⁹ | Judge- |
| | (nm) | (nm) | count | (nm) | (%) | nm | arcsec | arcsec | cm⁻² | cm⁻² | cm⁻² | ment |
| Experiment | 6 | 6 | 50 | 600 | 76 | 13.0 | 247 | 467 | 0.1 | 1.2 | 1.3 | A |
| Example 1 | | | | | | | | | | | | |
| Experiment | 12 | 12 | 25 | 600 | 85 | 8.9 | 252 | 448 | 0.1 | 1.1 | 1.2 | A |
| Example 2 | | | | | | | | | | | | |
| Experiment | 25 | 25 | 12 | 600 | 90 | 6.3 | 241 | 449 | 0.1 | 1.1 | 1.2 | A |
| Example 3 | | | | | | | | | | | | |
| Experiment | 50 | 50 | 6 | 600 | 100 | 5.8 | 250 | 458 | 0.1 | 1.1 | 1.3 | A |
| Example 4 | | | | | | | | | | | | |
| Experiment | 100 | 100 | 3 | 600 | 96 | 5.7 | 466 | 475 | 0.5 | 1.2 | 1.7 | A |
| Example 5 | | | | | | | | | | | | |
| Experiment | 25 | 12 | 16 | 592 | 68 | 21.0 | 341 | 475 | 0.2 | 1.2 | 1.5 | A |
| Example 6 | | | | | | | | | | | | |
| Experiment | 25 | 50 | 8 | 600 | 97 | 7.8 | 247 | 464 | 0.1 | 1.2 | 1.3 | A |
| Example 7 | | | | | | | | | | | | |
| Experiment | 25 | 75 | 6 | 600 | 92 | 6.0 | 237 | 468 | 0.1 | 1.2 | 1.3 | A |
| Example 8 | | | | | | | | | | | | |
| Experiment | 25 | 100 | 5 | 625 | 89 | 6.0 | 359 | 495 | 0.3 | 1.3 | 1.6 | A |
| Example 9 | | | | | | | | | | | | |
| Experiment | 25 | 125 | 4 | 600 | 90 | 4.7 | 322 | 498 | 0.2 | 1.4 | 1.6 | A |
| Example 10 | | | | | | | | | | | | |
| Experiment | 0 | 0 | 0 | 0 | 17 | 22.0 | 1134 | 919 | 2.7 | 4.6 | 7.3 | B |
| Example 11 | | | | | | | | | | | | |
| Experiment | 3 | 3 | 100 | 600 | 76 | 22.0 | 392 | 583 | 0.3 | 1.9 | 2.2 | B |
| Example 12 | | | | | | | | | | | | |
| Experiment | 200 | 200 | 1.5 | 600 | 75 | 17.0 | 799 | 748 | 1.3 | 3.1 | 4.4 | B |
| Example 13 | | | | | | | | | | | | |

FIG. 12 to FIG. 14 are graphs in which the lattice relaxation ratios with respect to the thicknesses of the first crystal layer and the second crystal layer, surface roughness RMS and dislocation densities of Experiment Examples 1 to 5 and Experiment Examples 12 and 13 are plotted. Experiment Examples 1 to 5, 12 and 13 are examples where the ratio of the thicknesses of the first crystal layer and the second crystal layer in the stress relaxation layer was set to 1:1, the total thickness of the stress relaxation layer was fixed to approximately 600 nm and the repetition period count was changed.

The graph in FIG. 12 shows that the lattice relaxation ratios exceeded 60% in all of the experiment examples, when the thickness of the first crystal layer and the second crystal layer exceeded 10 nm, the lattice relaxation ratio exceeded 80%, when the thickness exceeded 25 mm, the lattice relaxation ratio exceeded 90%, and when the first crystal layer and the second crystal layer became as thick as up 50 nm, the lattice relaxation ratio reached 100%.

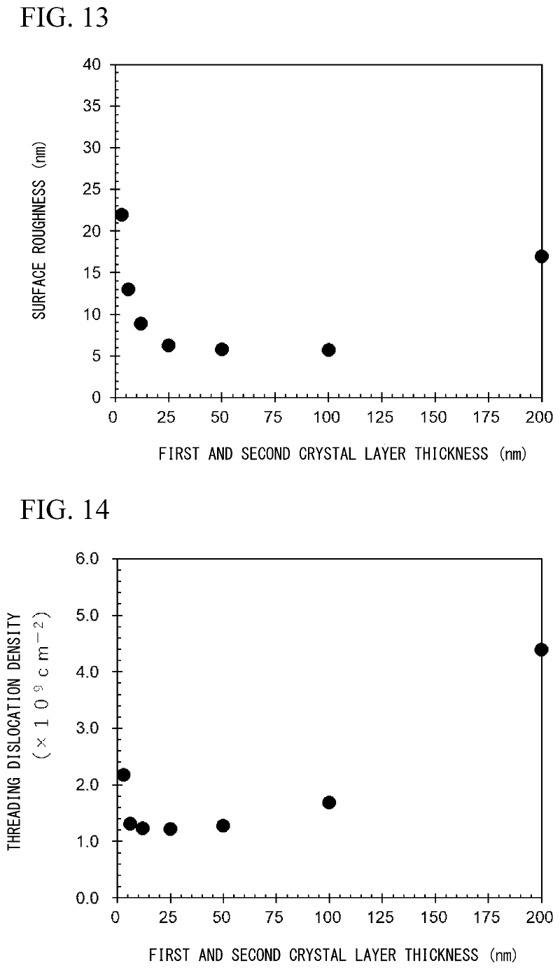

The graph in FIG. 13 shows that, as the thickness of the first crystal layer and the second crystal layer became thicker, the surface roughness became smaller. When the thickness of the first crystal layer and the second crystal layer was 6 nm or more, RMS became 15.0 nm or less, and it was possible to realize favorable flatness. In Experiment Examples 1 to 5, the full widths at half maximum of the X-ray rocking curves in the diffraction planes (102) were less than 550 arcsec, and the dislocation densities were lower than 2.0×10⁹ cm⁻² as shown by the graph in FIG. 14.

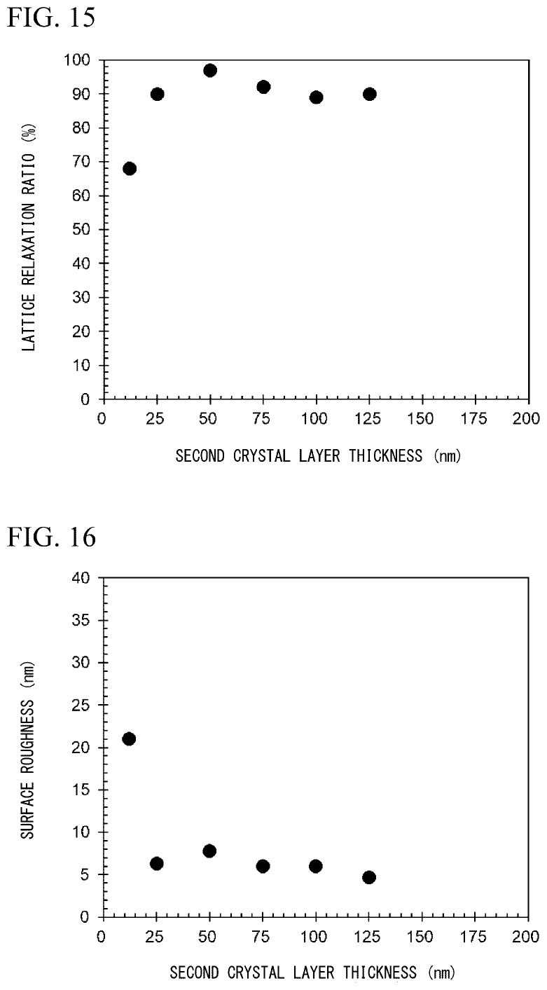

FIG. 15 to FIG. 17 are graphs in which the lattice relaxation ratios, surface roughness RMS and dislocation densities with respect to the thickness of the second crystal layer of Experiment Examples 3 and 6 to 10 are plotted. Experiment Examples 3 and 6 to 10 are examples where, while the thickness of the first crystal layer in the stress relaxation layer was fixed to 25 nm, the thickness of the second crystal layer was changed so that the thickness ratio between the first crystal layer and the second crystal layer reached 1:0.5 to 5.0 and the repetition period count was changed, whereby the total thickness of the stress relaxation layer was made to be approximately 600 or 625 nm.

The graph in FIG. 15 shows that, in Experiment Examples 3 and 6 to 10, the lattice relaxation ratios exceeded 60%, when the thickness of the second crystal layer exceeded 25 nm, the lattice relaxation ratio exceeded 90%, and when the second crystal layer became as thick as up 50 nm, the lattice relaxation ratio reached 97%. When the second crystal layer became thicker, the lattice relaxation ratio slightly decreased, but was maintained at 90%.

The graph in FIG. 16 shows that when the thickness of the second crystal layer was 12 nm, the surface roughness was 21.0 nm; however, when the thickness was 12 nm or more, the surface roughness was 10.0 nm or less and favorable flatness was obtained.

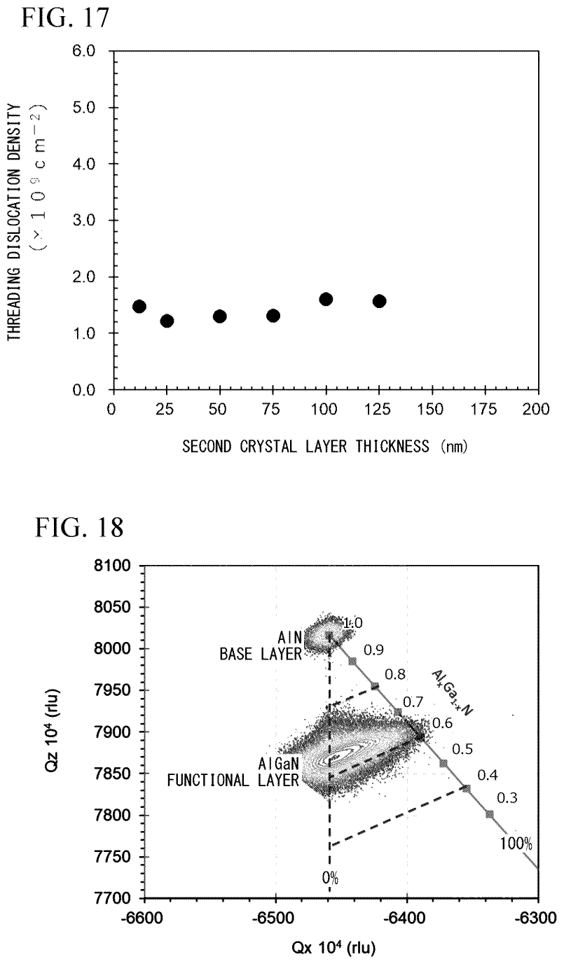

The graph in FIG. 17 shows that, in Experiment Examples 3 and 6 to 10, the full widths at half maximum of the X-ray rocking curves in the diffraction planes (102) were 550 arcsec or less, and the dislocation densities were lower than 2.0×10⁹ cm⁻².

As a result of visually confirming the compound semiconductor substrates of Experiment Examples 1 to 10 under fluorescent lighting at an illuminance of 2000 lux, the surfaces of all of the compound semiconductor substrates did not become white turbid and were mirror surfaces.

Therefore, in the present invention, the thickness of the first crystal layer was set to 6 nm or more and 125 nm or less, preferably 10 nm or more and 100 nm or less and more preferably 20 nm or more and 75 nm or less, and the thickness of the second crystal layer was set to 6 nm or more and 125 nm or less, preferably 10 nm or more and 100 nm or less and more preferably 20 nm or more and 75 nm or less.

For the compound semiconductor substrate of Experiment Example 11 where the stress relaxation layer was not formed, the lattice relaxation ratio, the surface roughness and the full widths at half maximum of the X-ray rocking curves in the diffraction planes (002) and (102) were evaluated in the same manner as in Experiment Examples 1 to 10.

A graph in FIG. 18 is an X-ray reciprocal lattice mapping image of a diffraction plane (−1-14) that became an asymmetrical plane of the compound semiconductor substrate of Experiment Example 11. The lattice relaxation ratio was calculated, and a result of 17% was obtained. That is, the lattice of the functional layer was not fully relaxed with respect to the base layer.

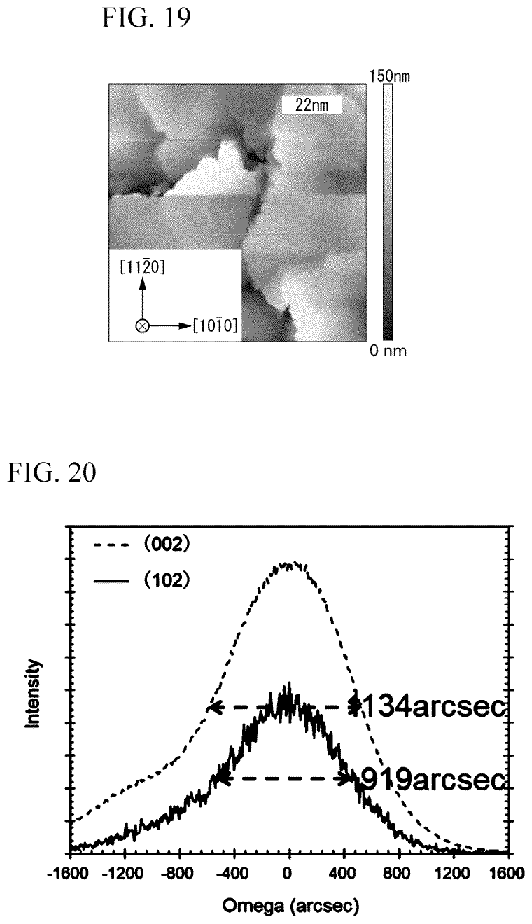

FIG. 19 is an atomic force microscope (AFM) image of a surface of the compound semiconductor substrate of Experiment Example 11 scanned within a 20 μm-square field of view. The surface roughness was 22.0 nm, which was caused by a number of large steps that were observed on the surface (the cause of the surface roughness).

A graph in FIG. 20 shows an X-ray rocking curve in a diffraction plane (102) of the functional layer of the compound semiconductor substrate of Experiment Example 11, and a full width at half maximum of 919 arcsec can be estimated from FIG. 20. When the threading dislocation density is calculated according to Non-Patent Document 9, the threading dislocation density was 7.3×10⁹ cm⁻².

In addition, as also shown in the graphs of FIGS. 12, 13 and 14, the lattice relaxation ratios of the compound semiconductor substrates of Experiment Examples 12 and 13 were 75% or higher, but the surface roughness from the atomic force microscope (AFM) image scanned within a 20 μm-square field of view exceeded 15.0 nm, the full width at half maximum of the X-ray rocking curve in the diffraction plane (102) exceeded 550 arcsec, and the threading dislocation density exceeded 2.0×10⁹ cm⁻².

As a result of visually confirming the compound semiconductor substrates of Experiment Examples 11 to 13 under fluorescent lighting at an illuminance of 2000 lux, the surfaces of the compound semiconductor substrates became white turbid.

### Example 2

An AlN template was prepared by forming AlN in a thickness of 300 to 400 nm as a base layer on a sapphire substrate (size: 50 mm in diameter), and a stress relaxation layer and a functional layer were sequentially formed thereon by a MOCVD method. A 25 nm-thick AlGaN layer as a first crystal layer of the stress relaxation layer and a 125 nm-thick AlGaN layer as a second crystal layer were formed in a composition ratio shown in Table 2, a laminate structure in which the first crystal layer and the second crystal layer were laminated together was repeatedly laminated four times, and each thickness and the repetition count were adjusted so that the total thickness of the stress relaxation layer reached approximately 600 nm. As the functional layer, a 2500 nm-thick Si-doped n-type Al_{0.62}Ga_{0.38}N layer was formed. The growth temperature was changed to be within a range of 1000° C. to 1150° C. Compound semiconductor substrates of Experiment Examples 14 to 17 were produced in combinations of (the Al composition ratio of the first crystal layer/the Al composition ratio of the second crystal layer) of (0.8/0.5), (0.8/0.35), (0.9/0.65) and (0.7/0.2).

### Comparative Example 2

An AlN template was prepared by forming AlN in a thickness of 300 to 400 nm as a base layer on a sapphire substrate (size: 50 mm in diameter), and a stress relaxation layer and a functional layer were sequentially formed thereon by a MOCVD method. A 25 nm-thick AlGaN layer as a first crystal layer of the stress relaxation layer and a 125 nm-thick AlGaN layer as a second crystal layer were formed in a composition ratio shown in Table 2, a laminate structure in which the first crystal layer and the second crystal layer were laminated together was repeatedly laminated four times, and each thickness and the repetition count were adjusted so that the total thickness of the stress relaxation layer reached approximately 600 nm. As the functional layer, a 2500 nm-thick Si-doped n-type Al_{0.62}Ga_{0.38}N layer was formed. The growth temperature was changed to be within a range of 1000° C. to 1150° C. A compound semiconductor substrate of Experiment Example 18 was produced in a combination of (the Al composition ratio of the first crystal layer/the Al composition ratio of the second crystal layer) of (0.7/0.1).

For the compound semiconductor substrates of Experiment Examples 14 to 18, aside from the relational formula (c1+c2−2×b)/(2×b), the lattice relaxation ratios, the surface roughness, the full widths at half maximum of the X-ray rocking curves in the diffraction planes (002) and (102) and the dislocation densities were evaluated in the same manner as in Example 1. The results are shown in Table 2. As b (the in-plane lattice constant b of the functional layer) in the relational formula (c1+c2−2×b)/(2×b), an in-plane lattice constant at an Al composition ratio of 0.62 of 0.3132 nm was used.

A case where the lattice relaxation ratio was 60% or higher and the full width at half maximum of the X-ray rocking curve in the diffraction plane (102) of the functional layer was less than 550 arcsec was regarded as pass (A), and a case where at least any of the lattice relaxation ratio of 60% or higher and the full width at half maximum of less than 550 arcsec was not satisfied was regarded as fail (B).

TABLE 2

| | First | Second | | | | | | | | Threading | |
|---|---|---|---|---|---|---|---|---|---|---|---|
| | crystal | crystal | | | | 002 Full | 102 Full | Screw | Edge | dislo- | |
| | layer Al | laye rAl | | | | width at | width at | dislo- | dislo- | cation | |
| | composition | composition | (c1 + c2 − | Lattice | Surface | half | half | cation | cation | density | |
| | lattice | lattice | 2 × b)/ | relaxation | roughness | maximum | maximum | 10⁹ | 10⁹ | 10⁹ | Judge- |
| | constant | constant | (2 × b) % | ratio (%) | nm | arcsec | arcsec | cm⁻² | cm⁻² | cm⁻² | ment |
| Experiment | 0.8 | 0.5 | −0.08 | 92 | 6.0 | 237 | 468 | 0.1 | 1.2 | 1.3 | A |
| Example 14 | 0.3114 nm | 0.3139 nm | | | | | | | | | |
| Experiment | 0.8 | 0.35 | 0.13 | 100 | 7.0 | 273 | 518 | 0.2 | 1.5 | 1.6 | A |
| Example 15 | 0.3114 nm | 0.3152 nm | | | | | | | | | |
| Experiment | 0.9 | 0.65 | −0.43 | 66 | 4.6 | 341 | 545 | 0.2 | 1.6 | 1.9 | A |
| Example 16 | 0.3105 nm | 0.3126 nm | | | | | | | | | |
| Experiment | 0.7 | 0.2 | 0.46 | 99 | 6.4 | 151 | 516 | 0.0 | 1.5 | 1.5 | A |
| Example 17 | 0.3122 nm | 0.3165 nm | | | | | | | | | |
| Experiment | 0.7 | 0.1 | 0.60 | 100 | 20.0 | 320 | 628 | 0.2 | 2.2 | 2.4 | B |
| Example 18 | 0.3136 nm | 0.3174 nm | | | | | | | | | |

Table 2 shows that the lattice relaxation ratios in the compound semiconductor substrates of Experiment Examples 14 to 17 all exceeded 60%, the surface roughness from the atomic force microscope (AFM) image scanned within a 20 μm-square field of view was all 7.0 nm or less, the full widths at half maximum of the X-ray rocking curves in the diffraction planes (102) were 550 arcsec or less, and the dislocation densities were lower than 2.0×10⁹ cm⁻². On the other hand, the lattice relaxation ratio in the compound semiconductor substrate of Experiment Example 18 was 100%, but the surface roughness was 20.0 nm, the full width at half maximum of the X-ray rocking curve in the diffraction plane (102) was 628 arcsec, and the threading dislocation density was 2.4×10⁹ cm⁻².

### Example 3

An AlN template was prepared by forming AlN in a thickness of 300 to 400 nm as a base layer on a sapphire substrate (size: 50 mm in diameter), and a stress relaxation layer, a functional layer and an active layer were sequentially formed thereon by a MOCVD method. A 30 nm-thick Al_{0.8}Ga_{0.2}N layer as a first crystal layer of the stress relaxation layer and a 30 nm-thick Al_{0.5}Ga_{0.5}N layer as a second crystal layer were formed, and a laminate structure in which the first crystal layer and the second crystal layer were laminated together was repeatedly laminated 30 times as a repetition period count so that the total thickness of the stress relaxation layer reached 1800 nm. As the functional layer, a 500 to 4000 nm-thick Si-doped n-type Al_{0.63}Ga_{0.37}N layer was formed. For the active layer, a 7.0 nm-thick Al_{0.60}Ga_{0.40}N layer as a first active crystal layer and a 3.5 nm-thick Al_{0.45}Ga_{0.55}N layer as a second active crystal layer were formed, and an active laminate structure in which the first active crystal layer and the second active crystal layer were laminated together was repeatedly laminated five times. The composition of each layer was changed by changing the ratio between an Al source gas and a Ga source gas. The growth temperature was changed to be within a range of 1000° C. to 1150° C. Compound semiconductor substrates of Experiment Examples 19 to 23 were produced as described above.

As the relationship between the in-plane lattice constants of the stress relaxation layer (the first crystal layer and the second crystal layer) and the functional layer, (c1+c2−2×b)/(2×b)≤±0.5% was set. In the formula, c1 is the in-plane lattice constant of the first crystal layer, c2 is the in-plane lattice constant of the second crystal layer, and b is the in-plane lattice constant of the functional layer.

### Comparative Example 3

An AlN template was prepared by forming AlN in a thickness of 300 to 400 nm as a base layer on a sapphire substrate (size: 50 mm in diameter), and a functional layer and an active layer were sequentially formed thereon by a MOCVD method. As the functional layer, a 500 to 4000 nm-thick Si-doped n-type Al_{0.62}Ga_{0.38}N layer was formed. For the active layer, a 7.0 nm-thick Al_{0.60}Ga_{0.40}N layer as a first active crystal layer and a 3.5 nm-thick Al_{0.45}Ga_{0.55}N layer as a second active crystal layer were formed, and an active laminate structure composed of the first active crystal layer and the second active crystal layer was repeatedly laminated five times. The composition of each layer was changed by changing the ratio between an Al source gas and a Ga source gas. The growth temperature was changed to be within a range of 1000° C. to 1150° C. Compound semiconductor substrates of Experiment Examples 24 to 26 were produced as described above. Conditions were set in the same manner as in Example 2 except that the stress relaxation layer was not formed.

For the compound semiconductor substrates of Experiment Examples 19 to 26, the surface roughness, lattice relaxation ratios, full widths at half maximum of the X-ray rocking curves in the diffraction planes (002) and (102) and light emission intensities in photoluminescence (PL) were evaluated. The surface roughness was evaluated with roughness of root mean square (RMS) within a 2 μm-square field of view of an atomic force microscope (AFM). The lattice relaxation ratio was evaluated from the peak positional relationship between the base layer and the functional layer in a (−1-14) diffraction plane, and the full width at half maximum of the X-ray rocking curve was measured by an X-ray diffraction method by ω/2θ. For PL, the peak intensity of a spectrum of light emission at 275 to 290 nm for which a 266 nm laser was used as excitation light was evaluated.

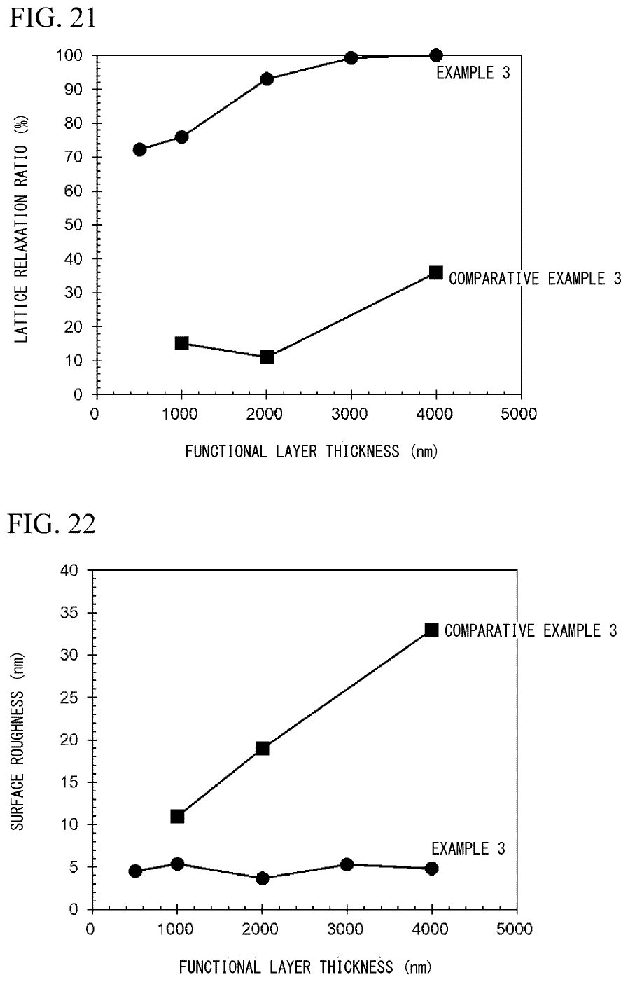

The evaluation results of the compound semiconductor substrates of Experiment Examples 19 to 26 regarding the lattice relaxation ratios, the surface roughness, the full widths at half maximum of the X-ray rocking curves in the diffraction planes (002) and (102), the light emission intensities in photoluminescence (PL) and the in-plane distributions of the sheet resistance are shown in Table 3 and FIG. 21 to FIG. 24.

A case where the lattice relaxation ratio was 60% or higher and the full width at half maximum of the X-ray rocking curve in the diffraction plane (102) of the functional layer was less than 550 arcsec was regarded as pass (A), and a case where at least any of the lattice relaxation ratio of 60% or higher and the full width at half maximum of less than 550 arcsec was not satisfied was regarded as fail (B).

TABLE 3

| | First | Second | | Stress | | Lattice | | 002 Full |
|---|---|---|---|---|---|---|---|---|
| | crystal | crystal | Repe- | relaxation | Functional | relax- | | width at |
| | layer | layer | tition | layer | layer | ation | Surface | half |
| | thickness | thickness | period | thickness | thickness | ratio | roughness | maximum |
| | (nm) | (nm) | count | (nm) | (nm) | (%) | nm | arcsec |
| Experiment | 30 | 30 | 30 | 1800 | 500 | 72 | 4.5 | 379 |
| Example 19 | | | | | | | | |
| Experiment | 30 | 30 | 30 | 1800 | 1000 | 76 | 5.4 | 352 |
| Example 20 | | | | | | | | |
| Experiment | 30 | 30 | 30 | 1800 | 2000 | 93 | 3.7 | 316 |
| Example 21 | | | | | | | | |
| Experiment | 30 | 30 | 30 | 1800 | 3000 | 99 | 5.3 | 308 |
| Example 22 | | | | | | | | |
| Experiment | 30 | 30 | 30 | 1800 | 4000 | 100 | 4.8 | 284 |
| Example 23 | | | | | | | | |
| Experiment | 0 | 0 | 0 | 0 | 1000 | 15 | 11.0 | 708 |
| Example 24 | | | | | | | | |
| Experiment | 0 | 0 | 0 | 0 | 2000 | 11 | 19.0 | 994 |
| Example 25 | | | | | | | | |
| Experiment | 0 | 0 | 0 | 0 | 4000 | 36 | 33.0 | 992 |
| Example 26 | | | | | | | | |

| | | | | Threading | | | |
|---|---|---|---|---|---|---|---|
| | 102 Full | Screw | Edge | dislo- | | | |
| | width at | dislo- | dislo- | cation | PL | In-plane | |
| | half | cation | cation | density | inten- | distri- | |
| | maximum | 10⁹ | 10⁹ | 10⁹ | sity × | bution | Judge- |
| | arcsec | cm⁻² | cm⁻² | cm⁻² | 1000 | % | ment |
| Experiment | 456 | 0.3 | 1.1 | 1.4 | 1 | 10 | A |
| Example 19 | | | | | | | |
| Experiment | 460 | 0.3 | 1.2 | 1.4 | 8 | 12 | A |
| Example 20 | | | | | | | |
| Experiment | 447 | 0.2 | 1.1 | 1.3 | 30 | 11 | A |
| Example 21 | | | | | | | |
| Experiment | 461 | 0.2 | 1.2 | 1.4 | 31 | 11 | A |
| Example 22 | | | | | | | |
| Experiment | 489 | 0.2 | 1.3 | 1.5 | 32 | 10 | A |
| Example 23 | | | | | | | |
| Experiment | 450 | 1.1 | 1.1 | 2.2 | 0 | 10 | B |
| Example 24 | | | | | | | |
| Experiment | 660 | 2.1 | 2.4 | 4.5 | 1 | 40 | B |
| Example 25 | | | | | | | |
| Experiment | 773 | 2.1 | 3.3 | 5.3 | 7 | 80 | B |
| Example 26 | | | | | | | |

A graph in FIG. 21 shows that the lattice relaxation ratios exceeded 70% in all of the compound semiconductor substrates of Experiment Examples 19 to 23 (Example 3), and when the thickness of the functional layer was 2000 nm or more, the lattice relaxation ratios exceeded 90%. On the other hand, the lattice relaxation ratios were lower than 60% in all of the compound semiconductor substrates of Experiment Examples 24 to 26 (Comparative Example 3).

A graph in FIG. 22 shows that RMS was less than 6.0 mm in all of the compound semiconductor substrates of Experiment Examples 19 to 23; however, on the other hand, RMS exceeded 6.0 nm in all of the compound semiconductor substrates of Experiment Examples 24 to 26.

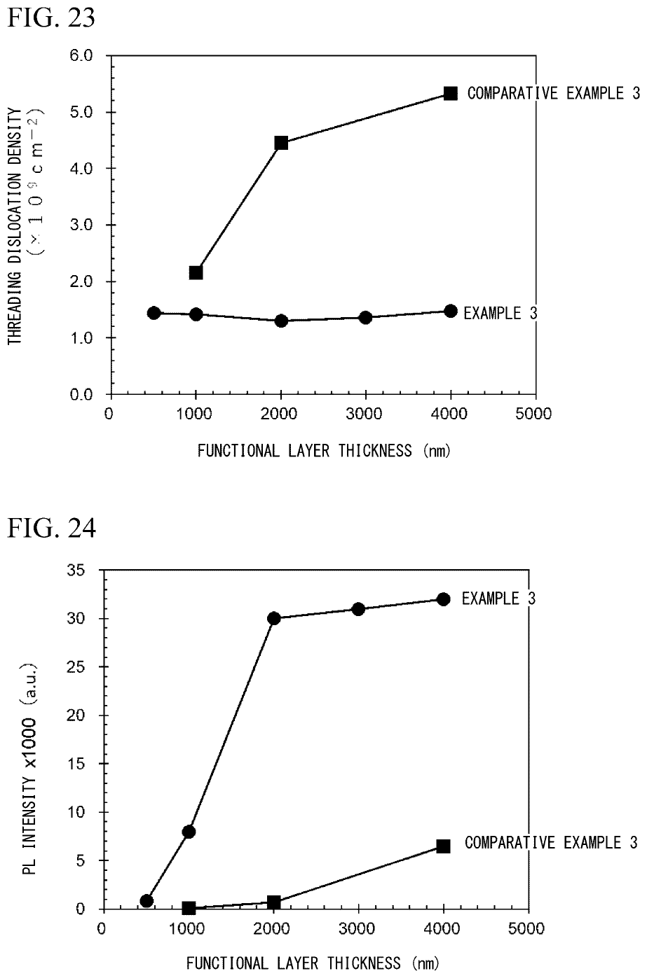

The full widths at half maximum of the (102) planes were less than 550 arcsec in all of the compound semiconductor substrates of Experiment Examples 19 to 23; however, on the other hand, the full widths at half maximum of the (102) planes were 450 arcsec when the thickness of the functional layer was 1000 nm, but exceeded 550 arcsec when the thickness of the functional layer was 2000 nm or more in the compound semiconductor substrates of Experiment Examples 24 to 26. As shown in FIG. 23, the dislocation densities were lower than 2.0×10⁹ cm⁻² in Experiment Examples 19 to 23, but the dislocation densities were 2.0×10⁹ cm⁻² or higher in Experiment Examples 24 to 26.

A graph in FIG. 24 shows that the PL light emission intensity was 8000 when the thickness of the functional layer was 1000 nm (Experiment Example 20) and the PL light emission intensity was 30000 when the thickness was 2000 nm (Experiment Example 21). On the other hand, in the compound semiconductor substrates of Experiment Examples 24 to 26, the PL light emission intensities were all less than 7000 regardless of the thickness of the functional layer.

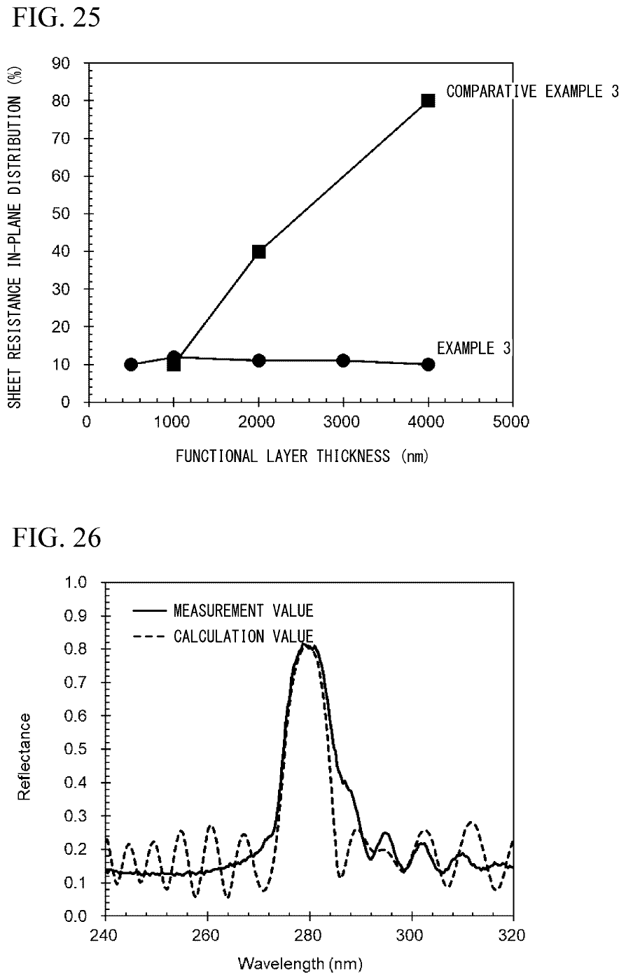

A graph in FIG. 25 shows that the in-plane distributions of the sheet resistance were 12% or less in all of the compound semiconductor substrates of Experiment Examples 19 to 23. On the other hand, the in-plane distributions were 10% when the thickness of the functional layer was 500 nm, but the in-plane distributions increased to 40% and 80% when the thickness was 2000 nm and 4000 nm in the compound semiconductor substrates of Experiment Examples 24 to 26.

As a result of visually confirming the compound semiconductor substrates of Experiment Examples 19 to 23 under fluorescent lighting at an illuminance of 2000 lux, the surfaces of all of the compound semiconductor substrates did not become white turbid and were mirror surfaces. On the other hand, as a result of visually confirming the compound semiconductor substrates of Experiment Examples 24 to 26 under fluorescent lighting at an illuminance of 2000 lux, the surfaces of the compound semiconductor substrates became white turbid.

### Example 4

An AlN template was prepared by forming AlN in a thickness of 300 to 400 nm as a base layer on a sapphire substrate (size: 50 mm in diameter), and a stress relaxation layer was sequentially formed thereon by a MOCVD method. A 30 nm-thick Al_{0.8}Ga_{0.2}N layer as a first crystal layer of the stress relaxation layer and a 30 nm-thick Al_{0.5}Ga_{0.5}N layer as a second crystal layer were formed, a laminate structure in which the first crystal layer and the second crystal layer were laminated together was repeatedly laminated 10 to 40 times as a repetition period count, and the total thickness of the stress relaxation layer was changed from 6000 nm to 2400 nm. The composition of each layer was changed by changing the ratio between an Al source gas and a Ga source gas. The growth temperature was changed to be within a range of 1000° C. to 1150° C. Compound semiconductor substrates of Experiment Examples 27 to 30 were produced as described above. Experiment Example 27 is an example where the repetition period count of the laminate structure in the stress relaxation layer was 10 and the total thickness of the stress relaxation layer was 600 nm. Experiment Example 28 is an example where the repetition period count of the laminate structure in the stress relaxation layer was 20 and the total thickness of the stress relaxation layer was 1200 nm. Experiment Example 29 is an example where the repetition period count of the laminate structure in the stress relaxation layer was 30 and the total thickness of the stress relaxation layer was 1800 nm. Experiment Example 30 is an example where the repetition period count of the laminate structure in the stress relaxation layer was 40 and the total thickness of the stress relaxation layer was 2400 nm.

The light reflection spectroscopy of the compound semiconductor substrates of Experiment Examples 27 to 30 was performed. In detail, the compound semiconductor substrates of Experiment Examples 27 to 30 were irradiated with a Xenon lamp and a halogen lamp using a reflection spectrometer manufactured by Ocean Insight, and the reflection intensities within a range of 240 to 320 nm were evaluated.

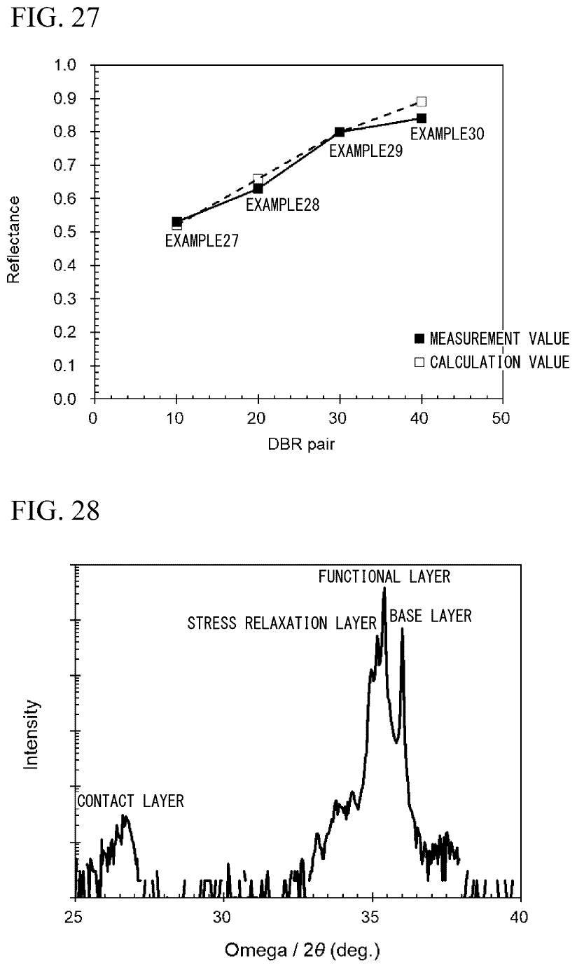

As one example of the result of the light reflection spectroscopy, FIG. 26 is a graph in which the reflection spectrum of Experiment Example 29 is plotted. In FIG. 26, the solid line indicates measurement values, and the dashed line indicates calculation values. As shown by the graph in FIG. 26, in Experiment Example 29, there is a peak of reflectance at a wavelength position of 280 nm and the maximum reflectance of 0.8 is shown. FIG. 27 is a graph in which the reflectance of Experiment Examples 27 to 30 is plotted, and DBR pair shown along the horizontal axis indicates the repetition period count of the laminate structure in the stress relaxation layer. In addition, it was found from the graph in FIG. 27 that, when the repetition period count of the stress relaxation layer is increased from 10 to 40, the reflectance increases from 0.53 up to 0.84.

### Example 5

An AlN template was prepared by forming AlN in a thickness of 300 to 400 nm as a base layer on a sapphire substrate (size: 50 mm in diameter), and a stress relaxation layer, a functional layer, an active layer and a contact layer were sequentially formed thereon by a MOCVD method. A 30 nm-thick Al_{0.8}Ga_{0.2}N layer as a first crystal layer of the stress relaxation layer and a 30 nm-thick Al_{0.5}Ga_{0.5}N layer as a second crystal layer were formed, and a laminate structure thereof was repeatedly laminated 30 times as a repetition period count so that the total thickness of the stress relaxation layer reached 1800 nm. As the functional layer, a 2500 nm-thick Si-doped n-type AlGaN layer (Si-doped Al_{0.63} Ga_{0.37}N) was formed. For the active layer, a 7.0 nm-thick Al_{0.60}Ga_{0.40}N layer as a first active crystal layer and a 3.5 nm-thick Al_{0.45} Ga_{0.55}N layer as a second active crystal layer were formed, and an active laminate structure composed of the first active crystal layer and the second active crystal layer was repeatedly laminated five times. As the contact layer, a 120 nm Mg-doped p-type BN contact layer was formed. The composition of each layer was changed by changing the ratio between an Al source gas and a Ga source gas. The growth temperature was changed to be within a range of 1000° C. to 1350° C. A compound semiconductor substrate of Experiment Example 31 was produced as described above.

The X-ray diffraction of the compound semiconductor substrate of Experiment Example 31 was measured. The X-ray diffraction was measured at 2θ within a range of 25 to 40 degrees in an ω/2θ measurement mode.

In a graph in FIG. 28, peaks at 20=26.72 degrees, 35.31 degrees, 35.39 degrees and 35.99 degrees are each a peak indicating the hexagonal BN contact layer, the stress relaxation layer, the AlGaN functional layer or the AlN base layer. For the AlGaN active layer, no X-ray diffraction peaks were observed due to the small thickness. It was confirmed that, even when the hexagonal BN contact layer grows at a high temperature, the crystal destruction of the AlGaN functional layer, the stress relaxation layer and the AlN base layer does not occur.

### REFERENCE SIGNS LIST

100, 200, 300, 400 Compound semiconductor substrate
102 Substrate
104 Base layer
106 Stress relaxation layer
106a First crystal layer
106b Second crystal layer
106c Laminate structure
106d Third crystal layer
106n n^{th} crystal layer
108 Functional layer
110 Interlayer
112 Active layer
114 Contact layer

The invention claimed is:

1. A compound semiconductor substrate comprising:
a base layer having an in-plane lattice constant of a;
a stress relaxation layer that relaxes strain that is received from the base layer; and
a functional layer having an in-plane lattice constant of b (a≠b),
wherein the base layer, the stress relaxation layer and the functional layer are disposed in order of the base layer, the stress relaxation layer and the functional layer,
in the functional layer, a region where a lattice is relaxed from a crystal lattice of the base layer is dominant, and
a threading dislocation density of the functional layer is lower than 2.0×10⁹ cm⁻².

2. The compound semiconductor substrate according to claim 1,
wherein an in-plane lattice constant of the stress relaxation layer is c that satisfies (a+c−2×b)/(2×b)≤±0.5%.

3. The compound semiconductor substrate according to claim 1,
wherein the stress relaxation layer is a laminate structure, and
the stress relaxation layer has a first crystal layer that is positioned in contact with a base layer side and has an in-plane lattice constant of c1 that is between a and b and a second crystal layer that is positioned in contact with a functional layer side of the first crystal layer and has an in-plane lattice constant of c2 that satisfies (c1+c2−2×b)/(2×b)≤±0.5%.

4. The compound semiconductor substrate according to claim 3,
wherein the first crystal layer in the stress relaxation layer has a thickness of 6 nm or more and 125 nm or less.

5. The compound semiconductor substrate according to claim 3,
wherein the second crystal layer in the stress relaxation layer has a thickness of 6 nm or more and 125 nm or less.

6. The compound semiconductor substrate according to claim 3,
wherein the stress relaxation layer has two or more periods as a repetition count of lamination composed of the first crystal layer and the second crystal layer, and
the stress relaxation layer has a thickness of 500 nm or more and 10000 nm or less.

7. The compound semiconductor substrate according to claim 3,
wherein, in the stress relaxation layer, the first crystal layer has a chemical composition of AlₓGa₁₋ₓN (0<x≤1.0), the second crystal layer has a chemical composition of Al Ga_{1-y}N (0≤y<1.0), and y<x is satisfied.

8. The compound semiconductor substrate according to claim 3,
wherein the stress relaxation layer further has a third crystal layer that is positioned in contact with a functional layer side of the second crystal layer and has an in-plane lattice constant of c3 that satisfies (c1+c2+c3−3×b)/(3×b)≤±0.5%.

9. The compound semiconductor substrate according to claim 8,
wherein the stress relaxation layer further has an n^{th} crystal layer that is positioned in contact with a functional layer side of the n−1^{th} crystal layer that is positioned on a functional layer side of the third crystal layer and has an in-plane lattice constant of cn that satisfies {c1+c2+ . . . +c(n−1)+cn−n×b}/(n×b)≤±0.5% provided that the n is an integer of four or higher.

10. The compound semiconductor substrate according to claim 3,
wherein the functional layer has a lattice relaxation ratio of 60% or higher with respect to the base layer.

11. The compound semiconductor substrate according to claim 3, further comprising:
an interlayer that is positioned in contact with the base layer between the base layer and the stress relaxation layer.

12. The compound semiconductor substrate according to claim 1, further comprising:
an active layer that is positioned on the functional layer and has an in-plane lattice constant that pseudomorphically matches the in-plane lattice constant b of the functional layer.

13. The compound semiconductor substrate according to claim 1, further comprising:
an active layer that is positioned on the functional layer and has an in-plane lattice constant that pseudomorphically matches the in-plane lattice constant b of the functional layer; and
a contact layer that is positioned on the active layer.

14. The compound semiconductor substrate according to claim 13,
wherein the contact layer has a larger band gap than that of the active layer.

15. The compound semiconductor substrate according to claim 12,
wherein the stress relaxation layer reflects 50% or more of light that is generated from the active layer.

16. The compound semiconductor substrate according to claim 1,
wherein a surface of the compound semiconductor substrate is a mirror surface.
